(19) United States
(12) Patent Application Publication
(10) Pub. No.: US 2006/0175298 A1
(43) Pub. Date: Aug. 10, 2006

(54) Method and composition for polishing a substrate

(76) Inventors: Junzi Zhao, Cupertino, CA (US); You Wang, Cupertino, CA (US); Feng Q. Liu, San Jose, CA (US); Stan D. Tsai, Fremont, CA (US)

Correspondence Address: PATTERSON & SHERIDAN, LLP, 3040 POST OAK BOULEVARD, SUITE 1500, HOUSTON, TX, 77056, US

(21) Appl. No.: 11/350,051

(22) Filed: Feb. 7, 2006

Related U.S. Application Data
(60) Provisional application No. 60/650,676, filed on Feb. 7, 2005.

(51) Int. Cl. C09K 13/00; C09K 13/06; H01L 21/461; B44C 1/22; C03C 25/68

(52) U.S. Cl. 216/88; 252/79.1; 252/79.4; 438/692

(57) ABSTRACT

Polishing compositions and methods for removing barrier materials from a substrate surface are provided. In one aspect, a composition is provided for removing at least a barrier material from a substrate surface including an acid based electrolyte system, one or more chelating agents, one or more pH adjusting agents to provide a pH between about 3 and about 11, and a solvent. The composition may be used in an electrochemical mechanical planarization process. The polishing compositions and methods described herein improve the effective removal rate of barrier materials from the substrate surface with a reduction in planarization type defects.

### CROSS-REFERENCE TO RELATED APPLICATIONS

This application claims benefit to U.S. Provisional Patent application Ser. No. 60/650,676, filed on Feb. 7, 2005, which application is incorporated by reference herein.

### BACKGROUND OF THE INVENTION

1. Field of the Invention

Embodiments of the present invention relate to compositions and methods for removing a conductive material from a substrate.

2. Background of the Related Art

Reliably producing sub-half micron and smaller features is one of the key technologies for the next generation of very large scale integration (VLSI) and ultra large-scale integration (ULSI) of semiconductor devices. However, as the limits of circuit technology are pushed, the shrinking dimensions of interconnects in VLSI and ULSI technology have placed additional demands on processing capabilities. Reliable formation of interconnects is important to VLSI and ULSI success and to the continued effort to increase circuit density and quality of individual substrates and die.

Multilevel interconnects are formed using sequential material deposition and material removal techniques on a substrate surface to form features therein. As layers of materials are sequentially deposited and removed, the uppermost surface of the substrate may become non-planar across its surface and require planarization prior to further processing. Planarization or “polishing” is a process in which material is removed from the surface of the substrate to form a generally even, planar surface. Planarization is useful in removing excess deposited material, removing undesired surface topography, and surface defects, such as surface roughness, agglomerated materials, crystal lattice damage, scratches, and contaminated layers or materials to provide an even surface for subsequent photolithography and other semiconductor manufacturing processes.

It is extremely difficult to planarize a metal surface, particularly a tungsten or copper surface, as by chemical mechanical polishing (CMP), which planarizes a layer by chemical activity as well as mechanical activity, of a damascene inlay as shown in FIGS. 1A and 1B, with a high degree of surface planarity. A damascene inlay formation process may include etching feature definitions 11 in an interlayer dielectric 10, such as a silicon oxide layer, depositing a barrier layer 13 in the feature definitions 11 and on a surface of the substrate, and depositing a thick layer of tungsten material 12 on the barrier layer 13 and substrate surface. The tungsten material 12 is chemical mechanically polished to expose the barrier layer. The barrier layer is then chemical mechanically polished to remove the barrier layer to expose the oxide layer 10 and filled feature definitions 11 as shown in FIG. 11A. Chemical mechanical polishing techniques to completely remove the barrier layer material often results in topographical defects, such as dishing and erosion, which may affect subsequent processing of the substrate.

Dishing occurs when a portion of the surface of the inlaid metal of the interconnection formed in the feature definitions in the interlayer dielectric is excessively polished, resulting in one or more concave depressions, which may be referred to as concavities or recesses. Referring to FIG. 1A, a damascene inlay of tungsten 12 in feature definitions 11 are formed with a barrier layer 13 in a damascene feature definition 11 formed in interlayer dielectric 10, for example, silicon dioxide. Subsequent to planarization, a portion of the tungsten 12 may be depressed by an amount D, referred to as the amount of dishing. Dishing is more likely to occur in wider or less dense features on a substrate surface.

Conventional planarization techniques also sometimes result in erosion, characterized by excessive polishing of the layer not targeted for removal, such as a dielectric layer 10 surrounding a filled feature definition. Referring to FIG. 1B, a tungsten fill 21 with a barrier layer 23 formed in a dense array of feature definitions 22 are inlaid in interlayer dielectric 20. Polishing the substrate may result in loss, or erosion E, of the dielectric 20 between the tungsten filled feature definitions. Erosion is observed to occur near narrower or denser features formed in the substrate surface.

Therefore, there is a need for compositions and methods for removing barrier materials from a substrate that minimizes the formation of topographical defects to the substrate during planarization.

### SUMMARY OF THE INVENTION

Aspects of the invention provide compositions and methods for removing barrier materials by an electrochemical polishing technique. In one aspect, a composition is provided for removing at least a barrier material from a substrate surface including an acid based electrolyte system, a first chelating agent having a nitrogen containing functional group, a second chelating agent having a carboxylate functional group, an organic acid salt, a pH adjuster to maintain a pH between about 3 and about 11, and a solvent. The polishing composition may further include one or more activating agents, one or more etching inhibitors, one or more oxidizers, or combinations thereof.

In another aspect, a method is provided for processing a substrate comprising a dielectric surface, feature definitions formed in the dielectric surface, a barrier material disposed in the feature definitions and the dielectric surface, and a conductive material disposed on the barrier material, the method including polishing the conductive material to expose the barrier material, disposing the substrate in a process apparatus comprising a first electrode and a second electrode, wherein the substrate is in electrical contact with the second electrode, providing a polishing composition between the first electrode and the substrate, wherein the polishing composition includes an acid based electrolyte system, a first chelating agent having a nitrogen containing functional group, a second chelating agent having a carboxylate functional group, an organic acid salt, a pH adjuster to maintain a pH between about 3 and about 11, and a solvent, applying a pressure between the substrate and a polishing article by use of a polishing head, providing relative motion between the substrate and the polishing article by mechanical means, applying a bias between the first electrode and the second electrode, and removing barrier material from the dielectric surface. The polishing composition may further include one or more activating agents, one or more etching inhibitors, one or more oxidizers, or combinations thereof.

### BRIEF DESCRIPTION OF THE DRAWINGS

So that the manner in which the above recited aspects of the present invention are attained and can be understood in detail, a more particular description of embodiments of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIGS. 1A and 1B schematically illustrate the phenomenon of dishing and erosion respectively;

FIG. 2 is a plan view of an electrochemical mechanical planarizing system;

FIG. 3 is a sectional view of one embodiment of a first electrochemical mechanical planarizing (Ecmp) station of the system of FIG. 2;

FIG. 4A is a partial sectional view of the first Ecmp station through two contact assemblies;

FIGS. 4B-C are sectional views of alternative embodiments of contact assemblies;

FIGS. 4D-E are sectional views of plugs;

FIGS. 5A and 5B are side, exploded and sectional views of one embodiment of a contact assembly;

FIG. 6 is one embodiment of a contact element;

FIG. 7 is a vertical sectional view of another embodiment of an Ecmp station; and

FIGS. 8A-8D are schematic cross-sectional views illustrating a polishing process performed on a substrate according to one embodiment.

### DETAILED DESCRIPTION OF THE PREFERRED EMBODIMENT

In general, aspects of the invention provide compositions and methods for removing at least a tungsten material from a substrate surface. The invention is described below in reference to a planarizing process for the removal of tungsten materials from a substrate surface by an electrochemical mechanical polishing (Ecmp) technique.

The words and phrases used herein should be given their ordinary and customary meaning in the art by one skilled in the art unless otherwise further defined. Chemical polishing should be broadly construed and includes, but is not limited to, planarizing a substrate surface using chemical activity. Electropolishing should be broadly construed and includes, but is not limited to, planarizing a substrate by the application of electrochemical activity. Electrochemical mechanical polishing (Ecmp) should be broadly construed and includes planarizing a substrate by the application of electrochemical activity, mechanical activity, and chemical activity to remove material from a substrate surface.

Anodic dissolution should be broadly construed and includes, but is not limited to, the application of an anodic bias to a substrate directly or indirectly which results in the removal of conductive material from a substrate surface and into a surrounding polishing composition. Polishing composition should be broadly construed and includes, but is not limited to, a composition that provides ionic conductivity, and thus, electrical conductivity, in a liquid medium, which generally comprises materials known as electrolyte components. The amount of each electrolyte component in polishing compositions can be measured in volume percent or weight percent. Volume percent refers to a percentage based on volume of a desired liquid component divided by the total volume of all of the liquid in the complete solution. A percentage based on weight percent is the weight of the desired component divided by the total weight of all of the liquid components in the complete solution.

Apparatus

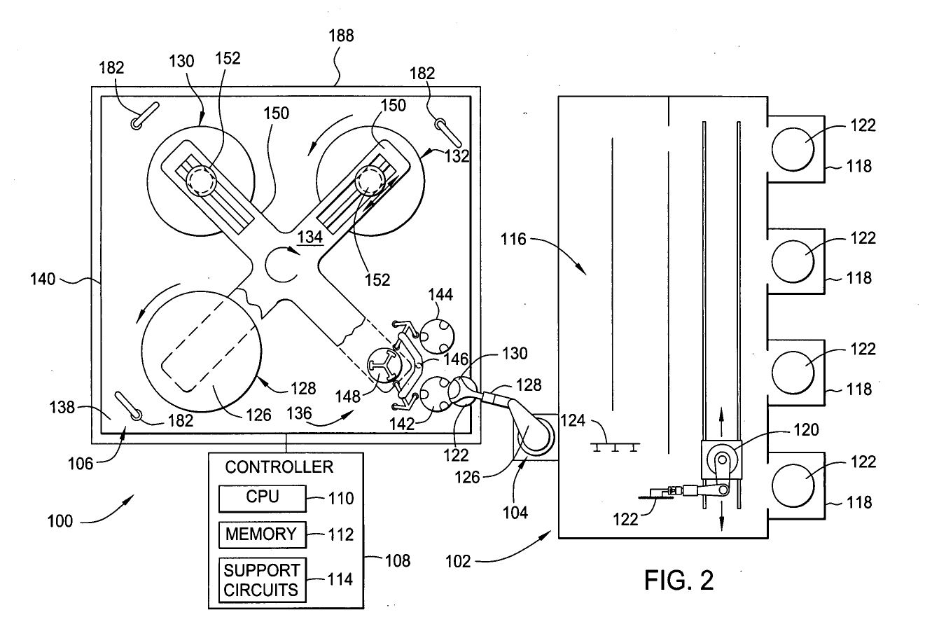

FIG. 2 is a plan view of one embodiment of a planarization system 100 having an apparatus for electrochemically processing a substrate. The exemplary system 100 generally comprises a factory interface 102, a loading robot 104, and a planarizing module 106. The loading robot 104 is disposed proximate the factory interface 102 and the planarizing module 106 to facilitate the transfer of substrates 122 therebetween.

A controller 108 is provided to facilitate control and integration of the modules of the system 100. The controller 108 comprises a central processing unit (CPU) 110, a memory 112, and support circuits 114. The controller 108 is coupled to the various components of the system 100 to facilitate control of, for example, the planarizing, cleaning, and transfer processes.

The factory interface 102 generally includes a cleaning module 116 and one or more wafer cassettes 118. An interface robot 120 is employed to transfer substrates 122 between the wafer cassettes 118, the cleaning module 116 and an input module 124. The input module 124 is positioned to facilitate transfer of substrates 122 between the planarizing module 106 and the factory interface 102 by grippers, for example vacuum grippers or mechanical clamps (not shown).

The planarizing module 106 includes at least a first electrochemical mechanical planarizing (Ecmp) station 128, disposed in an environmentally controlled enclosure 188. Examples of planarizing modules 106 that can be adapted to benefit from the invention include MIRRA® Chemical Mechanical Planarizing Systems, MIRRA MESA™ Chemical Mechanical Planarizing Systems, REFLEXION® Chemical Mechanical Planarizing Systems, REFLEXION® LK Chemical Mechanical Planarizing Systems, and REFLEXION LK Ecmp™ Chemical Mechanical Planarizing Systems, all available from Applied Materials, Inc. of Santa Clara, Calif. Other planarizing modules, including those that use processing pads, planarizing webs, or a combination thereof, and those that move a substrate relative to a planarizing surface in a rotational, linear or other planar motion may also be adapted to benefit from the invention.

In the embodiment depicted in FIG. 2, the planarizing module 106 includes one bulk Ecmp station 128, a second Ecmp station 130 and one CMP station 132. Bulk removal of conductive material from the substrate is performed through an electrochemical dissolution process at the bulk Ecmp station 128. After the bulk material removal at the bulk Ecmp station 128, residual conductive material is removed from the substrate at the residual Ecmp station 130 through a second electrochemical mechanical process. It is contemplated that more than one residual Ecmp stations 130 may be utilized in the planarizing module 106.

A barrier electrochemical mechanical planarizing process is performed at the planarizing station 132 after processing at the residual Ecmp station 130 by the barrier removal process described herein. Alternatively, an example of a conventional CMP process on a chemical mechanical polishing station for the barrier removal is described in U.S. patent application Ser. No. 10/187,857, filed Jun. 27, 2002, which is incorporated by reference in its entirety. It is contemplated that other CMP processes may be alternatively performed. As the CMP stations 132 are conventional in nature, further description thereof has been omitted for the sake of brevity.

It is contemplated that more than one Ecmp station may be utilized to perform the multi-step removal process after the bulk removal process performed at a different station. Alternatively, each of the first and second Ecmp stations 128, 130 may be utilized to perform both the bulk and multi-step conductive material removal on a single station. It is also contemplated that all Ecmp stations (for example 3 stations of the module 106 depicted in FIG. 2) may be configured to process the conductive layer with a two step removal process.

The exemplary planarizing module 106 also includes a transfer station 136 and a carousel 134 that are disposed on an upper or first side 138 of a machine base 140. In one embodiment, the transfer station 136 includes an input buffer station 142, an output buffer station 144, a transfer robot 146, and a load cup assembly 148. The input buffer station 142 receives substrates from the factory interface 102 by means of the loading robot 104. The loading robot 104 is also utilized to return polished substrates from the output buffer station 144 to the factory interface 102. The transfer robot 146 is utilized to move substrates between the buffer stations 142, 144 and the load cup assembly 148.

In one embodiment, the transfer robot 146 includes two gripper assemblies (not shown), each having pneumatic gripper fingers that hold the substrate by the substrate's edge. The transfer robot 146 may simultaneously transfer a substrate to be processed from the input buffer station 142 to the load cup assembly 148 while transferring a processed substrate from the load cup assembly 148 to the output buffer station 144. An example of a transfer station that may be used to advantage is described in U.S. Pat. No. 6,156,124, issued Dec. 5, 2000 to Tobin, which is herein incorporated by reference in its entirety.

The carousel 134 is centrally disposed on the base 140. The carousel 134 typically includes a plurality of arms 150, each supporting a planarizing head assembly 152. Two of the arms 150 depicted in FIG. 2 are shown in phantom such that the transfer station 136 and a planarizing surface 126 of the first Ecmp station 128 may be seen. The carousel 134 is indexable such that the planarizing head assemblies 152 may be moved between the planarizing stations 128, 130, 132 and the transfer station 136. One carousel that may be utilized to advantage is described in U.S. Pat. No. 5,804,507, issued Sep. 8, 1998 to Perlov, et al., which is hereby incorporated by reference in its entirety.

A conditioning device 182 is disposed on the base 140 adjacent each of the planarizing stations 128, 130, and 132. The conditioning device 182 periodically conditions the planarizing material disposed in the stations 128, 130, 132 to maintain uniform planarizing results.

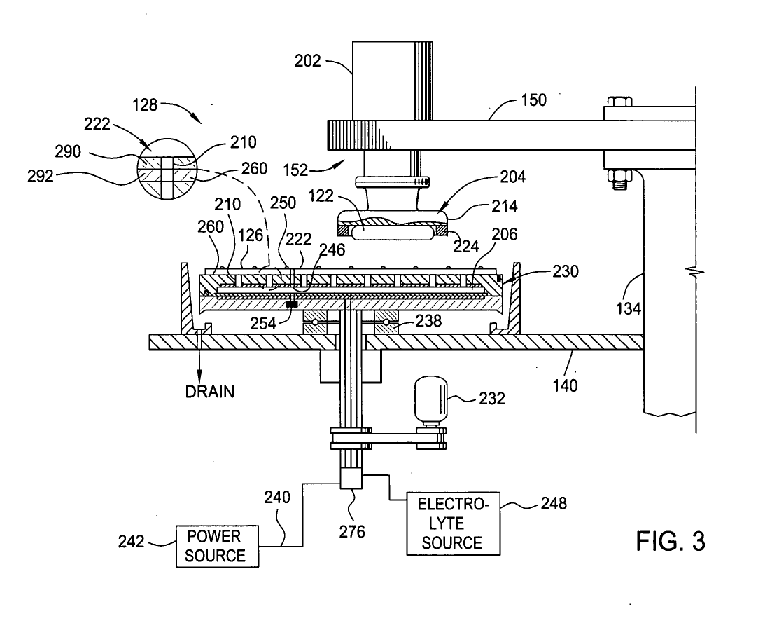

FIG. 3 depicts a sectional view of one of the planarizing head assemblies 152 positioned over one embodiment of the bulk Ecmp station 128. The planarizing head assembly 152 generally comprises a drive system 202 coupled to a planarizing head 204. The drive system 202 generally provides at least rotational motion to the planarizing head 204. The planarizing head 204 additionally may be actuated toward the bulk Ecmp station 128 such that the substrate 122 retained in the planarizing head 204 may be disposed against the planarizing surface 126 of the bulk Ecmp station 128 during processing. The drive system 202 is coupled to the controller 108 that provides a signal to the drive system 202 for controlling the rotational speed and direction of the planarizing head 204.

In one embodiment, the planarizing head may be a TITAN HEAD™ or TITAN PROFILER™ wafer carrier manufactured by Applied Materials, Inc. Generally, the planarizing head 204 comprises a housing 214 and retaining ring 224 that defines a center recess in which the substrate 122 is retained. The retaining ring 224 circumscribes the substrate 122 disposed within the planarizing head 204 to prevent the substrate from slipping out from under the planarizing head 204 while processing. The retaining ring 224 can be made of plastic materials such as polyphenylene sulfide (PPS), polyetheretherketone (PEEK), and the like, or conductive materials such as stainless steel, Cu, Au, Pd, and the like, or some combination thereof. It is further contemplated that a conductive retaining ring 224 may be electrically biased to control the electric field during Ecmp. Conductive or biased retaining rings tend to slow the polishing rate proximate the edge of the substrate. It is contemplated that other planarizing heads may be utilized.

The first Ecmp station 128 generally includes a platen assembly 230 that is rotationally disposed on the base 140. The platen assembly 230 is supported above the base 140 by a bearing 238 so that the platen assembly 230 may be rotated relative to the base 140. An area of the base 140 circumscribed by the bearing 238 is open and provides a conduit for the electrical, mechanical, pneumatic, control signals and connections communicating with the platen assembly 230.

Conventional bearings, rotary unions and slip rings, collectively referred to as rotary coupler 276, are provided such that electrical, mechanical, fluid, pneumatic, control signals and connections may be coupled between the base 140 and the rotating platen assembly 230. The platen assembly 230 is typically coupled to a motor 232 that provides the rotational motion to the platen assembly 230. The motor 232 is coupled to the controller 108 that provides a signal for controlling for the rotational speed and direction of the platen assembly 230.

A top surface 260 of the platen assembly 230 supports a processing pad assembly 222 thereon. The processing pad assembly may be retained to the platen assembly 230 by magnetic attraction, vacuum, clamps, adhesives and the like.

A plenum 206 is defined in the platen assembly 230 to facilitate uniform distribution of electrolyte to the planarizing surface 126. A plurality of passages, described in greater detail below, are formed in the platen assembly 230 to allow electrolyte, provided to the plenum 206 from an electrolyte source 248, to flow uniformly though the platen assembly 230 and into contact with the substrate 122 during processing. It is contemplated that different electrolyte compositions may be provided during different stages of processing.

The processing pad assembly 222 includes an electrode 292 and at least a planarizing portion 290. The electrode 292 is typically comprised of a conductive material, such as stainless steel, copper, aluminum, gold, silver and tungsten, among others. The electrode 292 may be solid, impermeable to electrolyte, permeable to electrolyte or perforated. At least one contact assembly 250 extends above the processing pad assembly 222 and is adapted to electrically couple the substrate being processed on the processing pad assembly 222 to the power source 242. The electrode 292 is also coupled to the power source 242 so that an electrical potential may be established between the substrate and electrode 292.

A meter (not shown) is provided to detect a metric indicative of the electrochemical process. The meter may be coupled or positioned between the power source 242 and at least one of the electrode 292 or contact assembly 250. The meter may also be integral to the power source 242. In one embodiment, the meter is configured to provide the controller 108 with a metric indicative of processing, such a charge, current and/or voltage. This metric may be utilized by the controller 108 to adjust the processing parameters in-situ or to facilitate endpoint or other process stage detection.

A window 246 is provided through the pad assembly 222 and/or platen assembly 230, and is configured to allow a sensor 254, positioned below the pad assembly 222, to sense a metric indicative of polishing performance. For example, the sensor 704 may be an eddy current sensor or an interferometer, among other sensors. The metric, provided by the sensor 254 to the controller 108, provides information that may be utilized for processing profile adjustment in-situ, endpoint detection or detection of another point in the electrochemical process. In one embodiment, the sensor 254 an interferometer capable of generating a collimated light beam, which during processing, is directed at and impinges on a side of the substrate 122 that is being polished. The interference between reflected signals is indicative of the thickness of the conductive layer of material being processed. One sensor that may be utilized to advantage is described in U.S. Pat. No. 5,893,796, issued Apr. 13, 1999, to Birang, et al., which is hereby incorporated by reference in its entirety.

Embodiments of the processing pad assembly 222 suitable for removal of conductive material from the substrate 122 may generally include a planarizing surface 126 that is substantially dielectric. Other embodiments of the processing pad assembly 222 suitable for removal of conductive material from the substrate 122 may generally include a planarizing surface 126 that is substantially conductive. At least one contact assembly 250 is provided to couple the substrate to the power source 242 so that the substrate may be biased relative to the electrode 292 during processing. Apertures 210, formed through the planarizing layer 290 and the electrode 292 and the any elements disposed below the electrode, allow the electrolyte to establish a conductive path between the substrate 122 and electrode 292.

In one embodiment, the planarizing portion 290 of the processing pad assembly 222 is a dielectric, such as polyurethane. Examples of processing pad assemblies that may be adapted to benefit from the invention are described in U.S. patent application Ser. No. 10/455,941, filed Jun. 6, 2003, entitled “Conductive Planarizing Article For Electrochemical Mechanical Planarizing”, and U.S. patent application Ser. No. 10/455,895, filed Jun. 6, 2003, entitled “Conductive Planarizing Article For Electrochemical Mechanical Planarizing,” both of which are hereby incorporated by reference in their entireties.

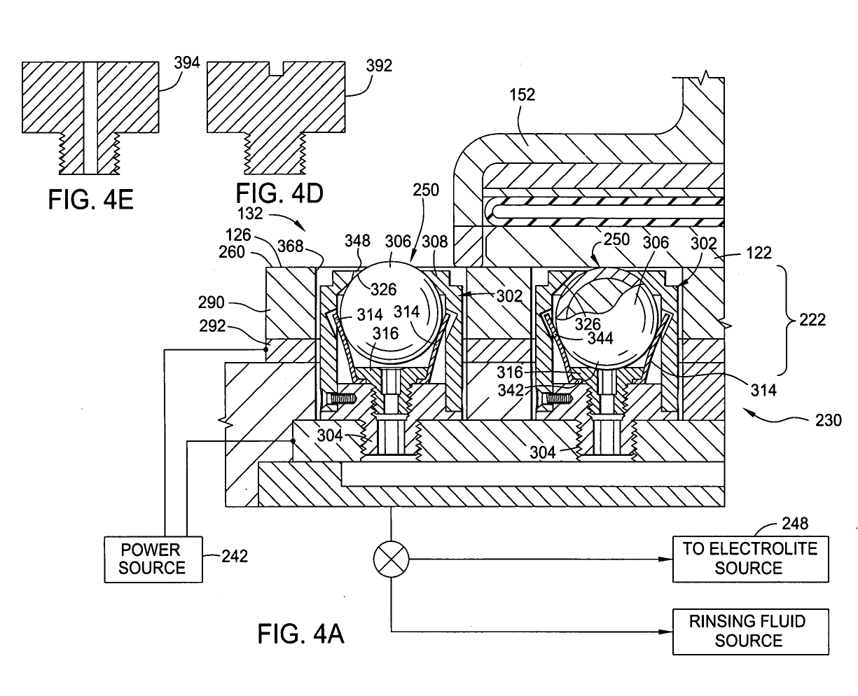

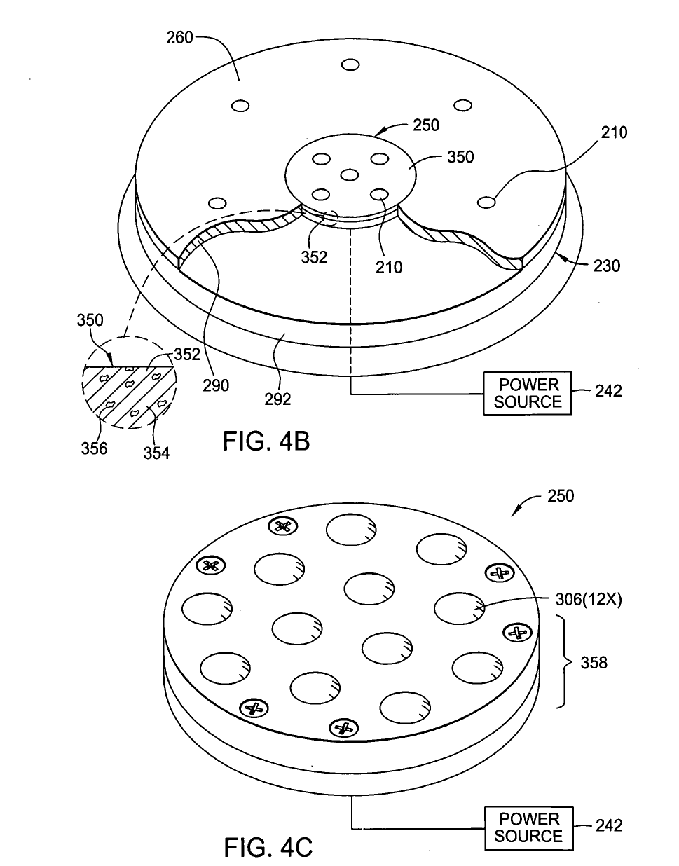

FIG. 4A is a partial sectional view of the first Ecmp station 128 through two contact assemblies 250, and FIGS. 5A-C are side, exploded and sectional views of one of the contact assemblies 250 shown in FIG. 5A. The platen assembly 230 includes at least one contact assembly 250 projecting therefrom and coupled to the power source 242 that is adapted to bias a surface of the substrate 122 during processing. The contact assemblies 250 may be coupled to the platen assembly 230, part of the processing pad assembly 222, or a separate element. Although two contact assemblies 250 are shown in FIG. 3A, any number of contact assemblies may be utilized and may be distributed in any number of configurations relative to the centerline of the platen assembly 230.

The contact assemblies 250 are generally electrically coupled to the power source 242 through the platen assembly 230 and are movable to extend at least partially through respective apertures 368 formed in the processing pad assembly 222. The positions of the contact assemblies 250 may be chosen to have a predetermined configuration across the platen assembly 230. For predefined processes, individual contact assemblies 250 may be repositioned in different apertures 368, while apertures not containing contact assemblies may be plugged with a stopper 392 or filled with a nozzle 394 (as shown in FIGS. 4D-E) that allows flow of electrolyte from the plenum 206 to the substrate. One contact assembly that may be adapted to benefit from the invention is described in U.S. patent application Ser. No. 10/445,239, filed May 23, 2003, by Butterfield, et al., and is hereby incorporated by reference in its entirety.

Although the embodiments of the contact assembly 250 described below with respect to FIG. 3A depicts a rolling ball contact, the contact assembly 250 may alternatively comprise a structure or assembly having a conductive upper layer or surface suitable for electrically biasing the substrate 122 during processing. For example, as depicted in FIG. 3B, the contact assembly 250 may include a pad structure 350 having an upper layer 352 made from a conductive material or a conductive composite (i.e., the conductive elements are dispersed integrally with or comprise the material comprising the upper surface), such as a polymer matrix 354 having conductive particles 356 dispersed therein or a conductive coated fabric, among others. The pad structure 350 may include one or more of the apertures 210 formed therethrough for electrolyte delivery to the upper surface of the pad assembly. Other examples of suitable contact assemblies are described in U.S. Provisional Patent Application Ser. No. 60/516,680, filed Nov. 3, 2003, by Hu, et al., which is hereby incorporated by reference in its entirety.

In one embodiment, each of the contact assemblies 250 includes a hollow housing 302, an adapter 304, a ball 306, a contact element 314 and a clamp bushing 316. The ball 306 has a conductive outer surface and is movably disposed in the housing 302. The ball 306 may be disposed in a first position having at least a portion of the ball 306 extending above the planarizing surface 126 and at least a second position where the ball 306 is substantially flush with the planarizing surface 126. It is also contemplated that the ball 306 may move completely below the planarizing surface 126. The ball 306 is generally suitable for electrically coupling the substrate 122 to the power source 242. It is contemplated that a plurality of balls 306 for biasing the substrate may be disposed in a single housing 358 as depicted in FIG. 3C.

The power source 242 generally provides a positive electrical bias to the ball 306 during processing. Between planarizing substrates, the power source 242 may optionally apply a negative bias to the ball 306 to minimize attack on the ball 306 by process chemistries.

The housing 302 is configured to provide a conduit for the flow of electrolyte from the source 248 to the substrate 122 during processing. The housing 302 is fabricated from a dielectric material compatible with process chemistries. A seat 326 formed in the housing 302 prevents the ball 306 from passing out of the first end 308 of the housing 302. The seat 326 optionally may include one or more grooves 348 formed therein that allow fluid flow to exit the housing 302 between the ball 306 and seat 326. Maintaining fluid flow past the ball 306 may minimize the propensity of process chemistries to attack the ball 306.

The contact element 314 is coupled between the clamp bushing 316 and the adapter 304. The contact element 314 is generally configured to electrically connect the adapter 304 and ball 306 substantially or completely through the range of ball positions within the housing 302. In one embodiment, the contact element 314 may be configured as a spring form.

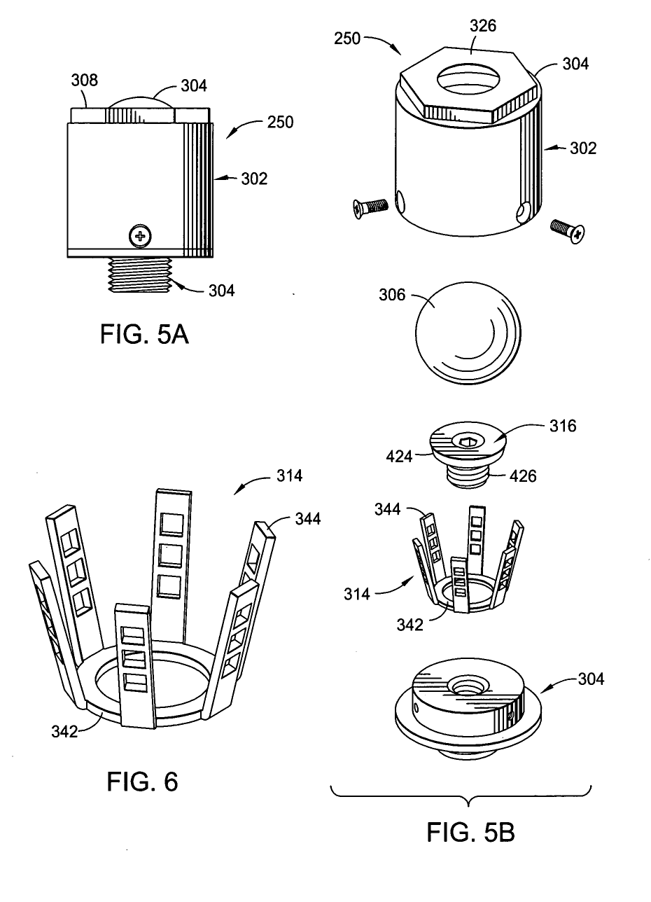

In the embodiment depicted in FIGS. 4A-E and 5A-C and detailed in FIG. 6, the contact element 314 includes an annular base 342 having a plurality of flexures 344 extending therefrom in a polar array. The flexure 344 is generally fabricated from a resilient and conductive material suitable for use with process chemistries. In one embodiment, the flexure 344 is fabricated from gold plated beryllium copper.

Returning to FIGS. 4A and 5A-B, the clamp bushing 316 includes a flared head 424 having a threaded post 422 extending therefrom. The clamp bushing 316 may be fabricated from either a dielectric or conductive material, or a combination thereof, and in one embodiment, is fabricated from the same material as the housing 302. The flared head 424 maintains the flexures 344 at an acute angle relative to the centerline of the contact assembly 250 so that the flexures 344 of the contact elements 314 are positioned to spread around the surface of the ball 306 to prevent bending, binding and/or damage to the flexures 344 during assembly of the contact assembly 250 and through the range of motion of the ball 306.

The ball 306 may be solid or hollow and is typically fabricated from a conductive material. For example, the ball 306 may be fabricated from a metal, conductive polymer or a polymeric material filled with conductive material, such as metals, conductive carbon or graphite, among other conductive materials. Alternatively, the ball 306 may be formed from a solid or hollow core that is coated with a conductive material. The core may be non-conductive and at least partially coated with a conductive covering.

The ball 306 is generally actuated toward the planarizing surface 126 by at least one of spring, buoyant or flow forces. In the embodiment depicted in FIG. 5, flow through the passages formed through the adapter 304 and clamp bushing 316 and the platen assembly 230 from the electrolyte source 248 urge the ball 306 into contact with the substrate during processing.

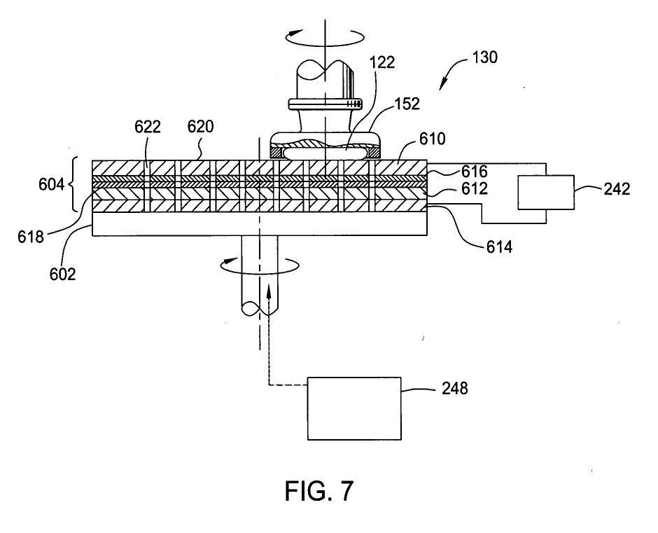

FIG. 7 is a sectional view of one embodiment of the second Ecmp station 130. The first and third Ecmp stations 128, 132 may be configured similarly. The second Ecmp station 130 generally includes a platen 602 that supports a fully conductive processing pad assembly 604. The platen 602 may be configured similar to the platen assembly 230 described above to deliver electrolyte through the processing pad assembly 604, or the platen 602 may have a fluid delivery arm (not shown) disposed adjacent thereto configured to supply electrolyte to a planarizing surface of the processing pad assembly 604. The platen assembly 602 includes at least one of a meter or sensor 254 (shown in FIG. 3) to facilitate endpoint detection.

In one embodiment, the processing pad assembly 604 includes interposed pad 612 sandwiched between a conductive pad 610 and an electrode 614. The conductive pad 610 is substantially conductive across its top processing surface and is generally made from a conductive material or a conductive composite (i.e., the conductive elements are dispersed integrally with or comprise the material comprising the planarizing surface), such as a polymer matrix having conductive particles dispersed therein or a conductive coated fabric, among others. The conductive pad 610, the interposed pad 612, and the electrode 614 may be fabricated into a single, replaceable assembly. The processing pad assembly 604 is generally permeable or perforated to allow electrolyte to pass between the electrode 614 and top surface 620 of the conductive pad 610. In the embodiment depicted in FIG. 7, the processing pad assembly 604 is perforated by apertures 622 to allow electrolyte to flow therethrough. In one embodiment, the conductive pad 610 is comprised of a conductive material disposed on a polymer matrix disposed on a conductive fiber, for example, tin particles in a polymer matrix disposed on a woven copper coated polymer. The conductive pad 610 may also be utilized for the contact assembly 250 in the embodiment of FIG. 3.

A conductive foil 616 may additionally be disposed between the conductive pad 610 and the interpose pad (subpad) 612. The foil 616 is coupled to a power source 242 and provides uniform distribution of voltage applied by the source 242 across the conductive pad 610. In embodiments not including the conductive foil 616, the conductive pad 610 may be coupled directly, for example, via a terminal integral to the pad 610, to the power source 242. Additionally, the pad assembly 604 may include an interposed pad 618, which, along with the foil 616, provides mechanical strength to the overlying conductive pad 610. Examples of suitable pad assemblies are described in the previously incorporated U.S. patent application Ser. Nos. 10/455,941 and 10/455,895.

Electrochemical Mechanical Processing:

An electrochemical mechanical polishing (Ecmp) technique using a combination of chemical activity, mechanical activity and electrical activity to remove barrier materials and planarize a substrate surface may be performed as follows. Barrier materials include titanium, titanium nitride, titanium silicon nitride, tantalum, tantalum nitride, tantalum silicon nitride, and combinations thereof. The barrier material may form a barrier between a tungsten material and surrounding dielectric material. Tungsten material includes tungsten, tungsten nitride, tungsten silicon nitride, and tungsten silicon nitride, among others. While the following process is described for titanium nitride removal, the invention contemplates the removal of other materials including ruthenium and any other barrier materials.

The removal of tungsten may be performed in one or more processing steps, for example, a single tungsten removal step or a bulk tungsten removal step and a residual tungsten removal step. Bulk material is broadly defined herein as any material deposited on the substrate in an amount more than sufficient to substantially fill features formed on the substrate surface. Residual material is broadly defined as any material remaining after one or more bulk or residual polishing process steps. Generally, in a two step process, the bulk removal during a first Ecmp process removes at least about 50% of the conductive layer, preferably at least about 70%, more preferably at least about 80%, for example, at least about 90%. The residual removal during a second Ecmp process removes most, if not all the remaining conductive material disposed on the barrier layer to leave behind the filled plugs.

The bulk removal Ecmp process may be performed on a first polishing platen and the residual removal Ecmp process on a second polishing platen of the same or different polishing apparatus as the first platen. In another embodiment, the residual removal Ecmp process may be performed on the first platen with the bulk removal process. The barrier material may be removed on a separate platen, such as the third platen in the apparatus described in FIG. 2. For example, the apparatus described above in accordance with the processes described herein may include three platens for removing tungsten material including, for example, a first platen to remove bulk material, a second platen for residual removal and a third platen for barrier removal, wherein the bulk and the residual processes are Ecmp processes and the barrier removal is an Ecmp process as described herein.

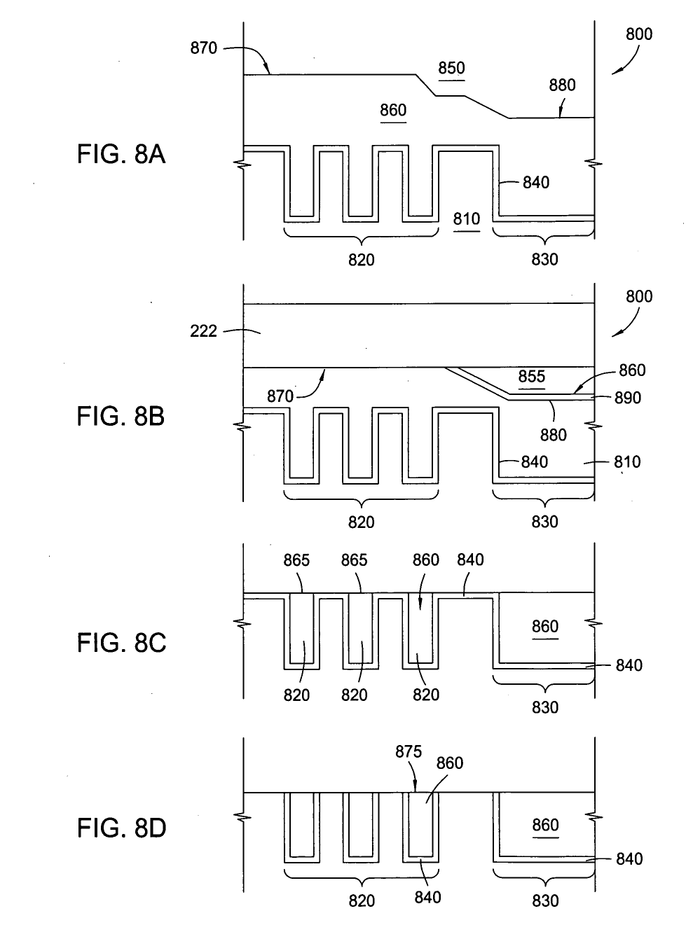

FIGS. 8A-8D are schematic cross-sectional views illustrating a polishing process performed on a substrate according to one embodiment for planarizing a substrate surface described herein. A first Ecmp process may be used to remove bulk tungsten material from the substrate surface as shown from FIGS. 8A-8B and then a second Ecmp process to remove residual tungsten materials as shown from FIGS. 8B-8C. The barrier Ecmp removal process described herein removes the barrier material as shown from FIGS. 8C-8D. The first Ecmp process produces to a fast removal rate of the tungsten layer and the second Ecmp process removes the remaining tungsten material. The barrier Ecmp process removers the barrier layer to form level substrate surfaces with reduced or minimal dishing and erosion of substrate features.

FIG. 8A is a schematic cross-sectional view illustrating one embodiment of a first electrochemical mechanical polishing technique for removal of a barrier layer used in tungsten processing. The substrate is disposed in a receptacle, such as a basin or platen containing a first electrode. The substrate 800 has a dielectric layer 810 patterned with narrow feature definitions 820 and wide feature definitions 830. Feature definitions 820 and feature definitions 830 have a barrier material 840, for example, titanium and/or titanium nitride, deposited therein followed by a fill of a conductive material 860, for example, tungsten. The deposition profile of the excess material includes a high overburden 870, also referred to as a hill or peak, formed over narrow feature definitions 820 and a minimal overburden 880, also referred to as a valley, over wide feature definitions 830.

Each of the electrochemical mechanical polishing processes (Ecmp) may be performed on the substrate as follows. A polishing composition 850 of one of the compositions described herein is provided to the substrate surface. The first polishing composition may be provided at a flow rate between about 100 and about 500 milliliters per minute, such as about 300 milliliters per minute, to the substrate surface.

An example of the polishing composition includes a first polishing composition for the bulk tungsten removal step includes between about 1 vol % and about 5 vol % of sulfuric acid, between about 1 vol % and about 5 vol % of phosphoric acid, between about 1 wt. % and about 5 wt. % of ammonium citrate, between about 0.5 wt. % and about 5 wt. % of ethylenediamine, a pH adjusting agent to provide a pH between about 6 and about 10, and deionized water. A further example of a bulk polishing composition includes about 2 vol % of sulfuric acid, about 2 vol % of phosphoric acid, about 2 wt. % of ammonium citrate, about 2 wt. % of ethylenediamine, potassium hydroxide to provide a pH between about 8.4 and about 8.9 and deionized water. An additional example of a bulk polishing composition includes about 2 vol % of sulfuric acid, about 0.2 vol % of phosphoric acid, about 2 wt. % of ammonium citrate, about 2 wt. % of ethylenediamine, 7 wt. % potassium hydroxide, a pH between about 8.4 and about 8.9, and deionized water. The composition has a conductivity of between about 60 and about 64 milliSiemens (mS). The bulk polishing composition described herein having strong etchants such as sulfuric acid as well as a basic pH, in which tungsten is more soluble, allow for an increased removal rate compared to the residual polishing composition described herein. Tungsten polishing compositions, both bulk and residual are more fully described in co-pending U.S. patent application Ser. No. 10/948,958, filed on Sep. 24, 2004, which is incorporated herein by reference to the extent not inconsistent with the disclosure and recited claims herein.

A polishing article coupled to a polishing article assembly containing a second electrode is then physically contacted and/or electrically coupled with the substrate through a conductive polishing article. The substrate surface and polishing article are contacted at a pressure less than about 2 pounds per square inch (lb/in² or psi) (13.8 kPa). Removal of the conductive material 860 may be performed with a process having a pressure of about 1 psi (6.9 kPa) or less, for example, from about 0.01 psi (69 Pa) to about 1 psi (6.9 kPa), such as between about 0.1 (0.7 kPa) psi and about 0.8 psi (5.5 kPa) or between about 0.1 (0.7 kPa) psi and less than about 0.5 psi (3.4 kPa). In one aspect of the process, a pressure of about 0.3 psi (2.1 kPa) is used.

The polishing pressures used herein reduce or minimize damaging shear forces and frictional forces for substrates containing low k dielectric materials. Reduced or minimized forces can result in reduced or minimal deformations and defect formation of features from polishing. Further, the lower shear forces and frictional forces have been observed to reduce or minimize formation of topographical defects, such as erosion of dielectric materials and dishing of conductive materials as well as reducing delamination, during polishing. Contact between the substrate and a conductive polishing article also allows for electrical contact between the power source and the substrate by coupling the power source to the polishing article when contacting the substrate.

Relative motion is provided between the substrate surface and the conductive pad assembly 222. The conductive pad assembly 222 disposed on the platen is rotated at a platen rotational rate of between about 7 rpm and about 50 rpm, for example, about 28 rpm, and the substrate disposed in a carrier head is rotated at a carrier head rotational rate between about 7 rpm and about 70 rpm, for example, about 37 rpm. The respective rotational rates of the platen and carrier head are believed to provide reduced shear forces and frictional forces when contacting the polishing article and substrate. Both the carrier head rotational speed and the platen rotational speed may be between about 7 rpm and less than 40 rpm. In one aspect of the invention, the processes herein may be performed with carrier head rotational speed greater than a platen rotational speed by a ratio of carrier head rotational speed to platen rotational speed of greater than about 1:1, such as a ratio of carrier head rotational speed to platen rotational speed between about 1.5:1 and about 12:1, for example between about 1.5:1 and about 3:1, to remove the tungsten material.

A bias from a power source 242 is applied between the two electrodes. The bias may be transferred from a conductive pad and/or electrode in the polishing article assembly 222 to the substrate 208. The process may also be performed at a temperature between about 20° C. and about 60° C.

The bias is generally provided at a current density up to about 100 mA/cm² which correlates to an applied current of about 40 amps to process substrates with a diameter up to about 300 mm. For example, a 200 mm diameter substrate may have a current density between about 0.01 mA/cm² and about 50 mA/cm², which correlates to an applied current between about 0.01 A and about 20 A, for example between about 4 mA/cm² to about 40 mA/cm², which correlates to an applied current from about 1.6 A to about 16 A. The invention also contemplates that the bias may be applied and monitored by volts, amps and watts. For example, in one embodiment, the power supply may apply a power between about 0.01 watts and 100 watts, a voltage between about 0.01 V and about 10 V, and a current between about 0.01 amps and about 10 amps. In one example of power application a voltage of between about 1.8 volts and about 4.5 volts, such as between about 2.6 volts and about 3.5 volts, is applied during application of the bulk polishing composition described herein to the substrate. The substrate is typically exposed to the polishing composition and power application for a period of time sufficient to remove the bulk of the overburden of tungsten disposed thereon.

The bias may be varied in power and application depending upon the user requirements in removing material from the substrate surface. For example, increasing power application has been observed to result in increasing anodic dissolution. The bias may also be applied by an electrical pulse modulation technique. Pulse modulation techniques may vary, but generally include a cycle of applying a constant current density or voltage for a first time period, then applying no current density or voltage or a constant reverse current density or voltage for a second time period. The process may then be repeated for one or more cycles, which may have varying power levels and durations. The power levels, the duration of power, an “on” cycle, and no power, an “off” cycle” application, and frequency of cycles, may be modified based on the removal rate, materials to be removed, and the extent of the polishing process. For example, increased power levels and increased duration of power being applied have been observed to increase anodic dissolution.

In one pulse modulation process for electrochemical mechanical polishing, the pulse modulation process comprises an on/off power technique with a period of power application, “on”, followed by a period of no power application, “off”. The on/off cycle may be repeated one or more times during the polishing process. The “on” periods allow for removal of exposed conductive material from the substrate surface and the “off” periods allow for polishing composition components and by-products of “on” periods, such as metal ions, to diffuse to the surface and complex with the conductive material. During a pulse modulation technique process it is believed that the metal ions migrate and interact with the corrosion inhibitors and/or chelating agents by attaching to the passivation layer in the non-mechanically disturbed areas. The process thus allows etching in the electrochemically active regions, not covered by the passivation layer, during an “on” application, and then allowing reformation of the passivation layer in some regions and removal of excess material during an “off” portion of the pulse modulation technique in other regions. Thus, control of the pulse modulation technique can control the removal rate and amount of material removed from the substrate surface.

The “on”/“off” period of time may be between about 1 second and about 60 seconds each, for example, between about 2 seconds and about 25 seconds, and the invention contemplates the use of pulse techniques having “on” and “off” periods of time greater and shorter than the described time periods herein. In one example of a pulse modulation technique, anodic dissolution power is applied between about 16% and about 66% of each cycle.

Non-limiting examples of pulse modulation technique with an on/off cycle for electrochemical mechanical polishing of materials described herein include: applying power, “on”, between about 5 seconds and about 10 seconds and then not applying power, “off”, between about 2 seconds and about 25 seconds; applying power for about 10 seconds and not applying power for 5 seconds, or applying power for 10 seconds and not applying power for 2 seconds, or even applying power for 5 seconds and not applying power for 25 seconds to provide the desired polishing results. The cycles may be repeated as often as desired for each selected process. One example of a pulse modulation process is described in commonly assigned U.S. Pat. No. 6,379,223, which is incorporated by reference herein to the extent not inconsistent with the claimed aspects and disclosure herein. Further examples of a pulse modulation process is described in co-pending United States Provisional patent application Ser. No. 10/611,805, entitled “Effective Method To Improve Surface Finish In Electrochemically Assisted Chemical Mechanical Polishing;” filed on Jun. 30, 2003, which is incorporated by reference herein to the extent not inconsistent with the claimed aspects and disclosure herein.

A removal rate of conductive material of up to about 15,000 Å/min can be achieved by the processes described herein. Higher removal rates are generally desirable, but due to the goal of maximizing process uniformity and other process variables (e.g., reaction kinetics at the anode and cathode) it is common for dissolution rates to be controlled from about 100 Å/min to about 15,000 Å/min. In one embodiment of the invention where the bulk tungsten material to be removed is less than 5,000 Å thick, the voltage (or current) may be applied to provide a removal rate from about 100 Å/min to about 5,000 Å/min, such as between about 2,000 Å/min to about 5,000 Å/min. The residual material is removed at a rate lower than the bulk removal rate and by the processes described herein may be removed at a rate between about 400 Å/min to about 1,500 Å/min.

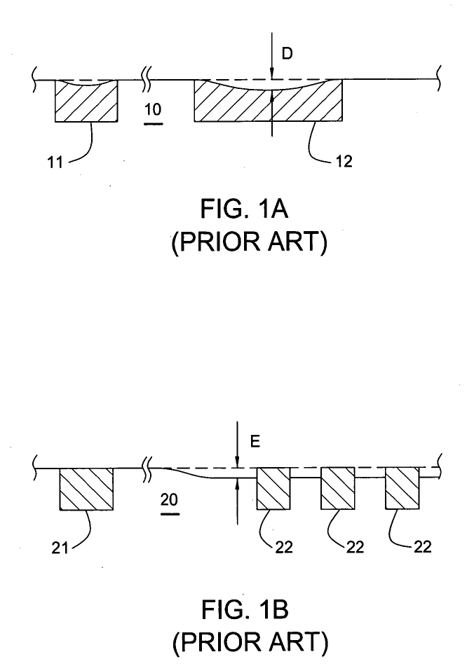

The second Ecmp process provides a reduced removal rate compared to the first Ecmp “bulk” process step in order to prevent excess metal removal from forming topographical defects, such as concavities or depressions known as dishing D, as shown in FIG. 1A, and erosion E as shown in FIG. 1B as well as reducing delamination during polishing. Therefore, a majority of the conductive layer 860 is removed at a faster rate during the first Ecmp process than the remaining or residual conductive layer 860 during the second Ecmp process. The two-step Ecmp process increases throughput of the total substrate processing and while producing a smooth surface with little or no defects. The second Ecmp step may comprise the first Ecmp step with a reduced bias and the same composition. Alternatively, a second composition may be used for the second Ecmp step.

FIG. 8B illustrates the initiation of the second Ecmp polishing step after at least about 50% of the conductive material 860 was removed after the bulk removal of the first Ecmp process, for example, about 90%. After the first Ecmp process, conductive material 860 may still include the high overburden 870, peaks, and/or minimal overburden 880, valleys, but with a reduced proportionally size. However, conductive material 860 may also be rather planar across the substrate surface (not pictured).

The second conductive material polishing step, the residual polishing step, may be performed as described above for the bulk polishing step with additional details regarding the following processing parameters. The second, residual polishing composition may be provided at a flow rate between about 150 and about 500 milliliters per minute, such as about 200 milliliters per minute, to the substrate surface.

An example of the second polishing composition for the residual removal step includes between about 0.2 vol % and about 2 vol % of sulfuric acid or derivative thereof, between about 0.2 vol % and about 2 vol % of phosphoric acid or derivative thereof, between about 0.1 wt. % and about 2 wt. % of a pH adjusting agent, between about 0.1 wt. % and about 2 wt. % of a chelating agent, between about 0.001 vol % and about 0.5 vol % of a passivating polymeric material, a pH between about 5 and about 10, and a solvent. A further example of a polishing composition includes about 0.5 vol % of sulfuric acid, about 1.5 vol % of phosphoric acid, about 0.5 wt. % of ammonium citrate, about 0.1 vol % of 70000 molecular weight polyethylene imine, about 4 wt. % of ammonium hydroxide to provide a pH of about 6. The composition has a conductivity of between about 30 and about 60 milliSiemens (mS).

Removal of the conductive material 860 may be performed with the pressure described for the bulk processing step above, and generally includes a process having a pressure of about 1 psi (6.9 kPa) or less, for example, from about 0.01 psi (69 Pa) to about 1 psi (6.9 kPa), such as between about 0.1 (0.7 kPa) psi and about 0.8 psi (5.5 kPa). In one aspect of the process, a pressure of about 0.3 psi (2.1 kPa) or less is used. Alternatively, the pressure of the second Ecmp step may be reduced compared to the first Ecmp step to further reduce the removal rate of the tungsten material. Contact between the substrate and a conductive polishing article also allows for electrical contact between the power source and the substrate by coupling the power source to the polishing article when contacting the substrate.

Relative motion is provided between the substrate surface and the conductive pad assembly 222. The conductive pad assembly 222 disposed on the platen is rotated at a rotational rate of between about 7 rpm and about 50 rpm, for example, about 7 rpm, and the substrate disposed in a carrier head is rotated at a rotational rate between about 7 rpm and about 70 rpm, for example, about 23 rpm. The respective rotational rates of the platen and carrier head are believed to provide reduce shear forces and frictional forces when contacting the polishing article and substrate.

The bias applied for the second Ecmp step uses a power level less than the power level of the bulk polishing process. For example, for the residual removal process, the power application is of a voltage of between about 1.8 volts and about 2.4, such as 2.2 volts. The substrate is typically exposed to the polishing composition and power application for a period of time sufficient to remove at least a portion or all of the desired material disposed thereon. The process may also be performed at a temperature between about 20° C. and about 60° C.

The polymeric inhibitor of the second composition is believed to form a passivation layer 890 on the surface of the exposed tungsten material as shown in FIG. 8B. The passivation layer is formed by a physical and chemical interaction between the polymeric material and the exposed tungsten material. The passivation layer is believed to chemically and/or electrically insulate material disposed on a substrate surface. The passivation layer 890 provides a reduce removal rate when formed over portions of the tungsten material, and allows a higher removal rate at areas of the substrate surface where the passivation layer 890 is not formed, such as when removed by physical contact with the polishing pad 222. Mechanical abrasion by a conductive polishing article removes the passivation layer 890 that insulates or suppresses the current for anodic dissolution, such that areas of high overburden are preferentially removed over areas of minimal overburden as the passivation layer 890 is retained in areas of minimal or no contact with the conductive pad assembly 222. The removal rate of the conductive material 860 covered by the passivation layer 890 is less than the removal rate of conductive material without the passivation layer 890. As such, the excess material disposed over narrow feature definitions 820 and the substrate field is removed at a higher rate than over wide feature definitions 830 still covered by the passivation layer 890.

The thickness and density of the passivation layer 890 can dictate the extent of chemical reactions and/or amount of anodic dissolution. For example, a thicker or denser passivation layer 890 has been observed to result in less anodic dissolution compared to thinner and less dense passivation layers. Thus, control of the composition of pH of the composition, i.e., polymeric inhibitors and additional compounds, allow control of the removal rate and amount of material removed from the substrate surface.

Referring to FIG. 8C, most, if not all of the conductive layer 860 is removed to expose barrier layer 840 and conductive trenches 865 by polishing the substrate with a second, residual, Ecmp process including the second Ecmp polishing composition described herein. The conductive trenches 865 are formed by the remaining conductive material 860.

Referring to FIG. 8D, barrier material may then be polished by a third Ecmp polishing step to provide a planarized substrate surface containing conductive trenches 875. The polishing pad may be a fully conductive polishing pad, for example, as recited herein and shown in FIG. 7. The barrier polishing composition provides for selective removal of barrier material to tungsten and dielectric (oxide) material at a barrier removal rate to tungsten removal rate at between about 30:1 and about 80:1, such as about 60:1, and a barrier removal rate to dielectric (oxide) removal rate of between about 3:1 and about 6:1, such as about 4:1.

A barrier polishing composition as described herein is provided to the substrate surface. The barrier polishing composition may be provided at a flow rate between about 50 and about 500 milliliters per minute, such as about 100 milliliters per minute, to the substrate surface.

A suitable barrier polishing composition for the barrier removal step as described herein includes between about 0.2 wt. % and about 20 wt. % of phosphoric acid or derivative thereof, such as between about 4 wt. % and about 10 wt. %; between about 0.1 wt. % and about 10 wt. % of a chelating agent, such as between about 2 wt. % and about 8 wt. %; sufficient pH adjusting agent to provide a pH between about 2 and about 11, and a solvent. An example of a barrier polishing composition includes about 8 wt. % of phosphoric acid, about 5 wt. % of ethylenediamine, about 3 wt. % of glycine, about 1 wt. % of ammonium hydrogen citrate, potassium hydroxide to provide a pH of about 3.5, and water. Another example of a barrier polishing composition includes about 8 wt. % of phosphoric acid, about 5 wt. % of ethylenediamine, about 3 wt. % of glycolic acid, about 1 wt. % of ammonium hydrogen citrate, potassium hydroxide to provide a pH of about 3.5; and water. Another example of a barrier polishing composition includes about 5 wt. % of phosphoric acid, about 3 wt. % of ethylenediamine, about 3 wt. % of glycolic acid, about 1 wt. % of ammonium hydrogen citrate, potassium hydroxide to provide a pH of about 3.5, and water.

The mechanical abrasion in the barrier removal process are performed as described in the first Ecmp process step at a contact pressure of less than about 2 pounds per square inch (lb/in² or psi) (13.8 kPa) between the polishing pad and the substrate. Removal of the barrier material 840 may be performed with a process having a pressure of about 1.5 psi (10.4 kPa) or less, for example, from about 0.1 psi (0.7 kPa) to about 1.0 psi (10.4 kPa), such as between about 0.3 (2.1 kPa) psi and about 0.5 psi (3.5 kPa). Contact between the substrate and a conductive polishing article also allows for electrical contact between the power source and the substrate by coupling the power source to the polishing article when contacting the substrate.

Relative motion is provided between the substrate surface and the conductive pad assembly 222. The conductive pad assembly 222 disposed on the platen is rotated at a rotational rate of between about 3 rpm and about 55 rpm, such as between about 7 rpm and about 21 rpm, for example 21 rpm, and the substrate disposed in a carrier head is rotated at a rotational rate between about 3 rpm and about 55 rpm, such as between about 11 rpm and about 40 rpm, for example, about 30 rpm. The respective rotational rates of the platen and carrier head are believed to provide reduce shear forces and frictional forces when contacting the polishing article and substrate.

The bias as applied for the barrier Ecmp step is as described above with regard to the first Ecmp processing step. In one embodiment of the power application for the barrier removal process, an applied voltage of between about 2 volts and about 4, such as 3.2 volts is used during processing. The substrate is typically exposed to the barrier polishing composition and power application for a period of time sufficient to remove at least a portion or all of the desired barrier material disposed thereon. The process may also be performed at a temperature between about 20° C. and about 60° C.

After conductive material and barrier material removal processing steps, the substrate may then be buffed to minimize surface defects. Buffing may be performed with a soft polishing article, i.e., a hardness of about 40 or less on the Shore D hardness scale as described and measured by the American Society for Testing and Materials (ASTM), headquartered in Philadelphia, Pa., at reduced polishing pressures, such as about 2 psi or less.

Optionally, a cleaning solution may be applied to the substrate after each of the polishing processes to remove particulate matter and spent reagents from the polishing process as well as help minimize metal residue deposition on the polishing articles and defects formed on a substrate surface. An example of a suitable cleaning solution is ELECTRA CLEAN™, commercially available from Applied Materials, Inc., of Santa Clara, Calif.

Finally, the substrate may be exposed to a post polishing cleaning process to reduce defects formed during polishing or substrate handling. Such processes can minimize undesired oxidation or other defects in copper features formed on a substrate surface. An example of such a post polishing cleaning is the application of ELECTRA CLEAN™, commercially available from Applied Materials, Inc., of Santa Clara, Calif.

It has been observed that substrate planarized by the processes described herein have exhibited reduced topographical defects, such as dishing and erosion, reduced residues, improved planarity, and improved substrate finish.

Barrier Polishing Composition

In one aspect, polishing compositions that can selectively polish a barrier material, such as titanium and titanium nitride, to a conductive fill material, such as tungsten or copper. Generally, the polishing composition comprises including an acid based electrolyte system, one or more chelating agents, one or more pH adjusting agents to provide a pH between about 3 and about 11, and a solvent. The polishing composition may further include one or more activating agents, one or more etching inhibitors, one or more oxidizers, or combinations thereof. It is believed that the polishing compositions described herein improve the effective removal rate of barrier materials from the substrate surface, during Ecmp, with a reduction in planarization type defects.

Although the barrier polishing compositions are particularly useful for removing titanium and titanium nitride, it is believed that the polishing compositions also may be used for the removal of other barrier materials including, for example, tantalum, tantalum nitride, tungsten, tungsten nitride, ruthenium, and combinations thereof. Mechanical abrasion, such as from contact with the conductive polishing article 203 and/or abrasives, may to improve planarity and improve removal rate of barrier materials.

The barrier polishing composition includes an acid based electrolyte system for providing electrical conductivity. Suitable acid based electrolyte systems include, for example, sulfuric acid based electrolytes, phosphoric acid based electrolytes, or combinations thereof. Suitable acid based electrolyte systems include an acid based electrolyte as well as acid electrolyte derivatives, including ammonium, potassium, sodium, calcium and metal salts thereof. The acid based electrolyte system may comprise two or more acid based electrolytes, such as a combination of sulfuric acid and phosphoric acid. The acid based electrolyte system may also buffer the composition to maintain a desired pH level for processing a substrate.

Examples of suitable acid based electrolytes include compounds having a phosphate group (PO₄³⁻), such as, phosphoric acid, metal phosphate salts, potassium phosphates (KₓH₍₃₋ₓ₎PO₄) (x=1, 2 or 3), such as potassium dihydrogen phosphate (KH₂PO₄), dipotassium hydrogen phosphate (K₂HPO₄), ammonium phosphates ((NH₄)ₓH₍₃₋ₓ₎PO₄) (x=1, 2 or 3), such as ammonium dihydrogen phosphate ((NH₄)H₂PO₄), diammonium hydrogen phosphate ((NH₄)₂HPO₄), and compounds having a sulfate group (SO₄²⁻), such as sulfuric acid (H₂SO₄), metal sulfuric salts, ammonium hydrogen sulfate ((NH₄)HSO₄), ammonium sulfate, ((NH₄)ₓH₍₂₋ₓ₎SO₃) (x=1 or 2), potassium sulfates (KₓH₍₂₋ₓ₎SO₄) (x=1 or 2), derivatives thereof and combinations thereof. The invention also contemplates that conventional electrolytes known and unknown may also be used in forming the composition described herein using the processes described herein.

The acid based electrolyte system may contains an acidic component that can take up about 0.1 and about 30 percent by weight (wt. %) or volume (vol %) of the total composition of solution to provide suitable conductivity for practicing the processes described herein. Examples of acidic components include sulfuric acid and/or phosphoric acid and may be present in the polishing composition in amounts between about 1.5 wt. % and about 15 wt. %, for example, between about 3 wt. % and about 12 wt. % of phosphoric acid may be used in the barrier polishing composition. The acid based electrolyte may also be added in solution, for example, the 8 wt. % of phosphoric acid may be from 85% aqueous phosphoric acid solution for an actual phosphoric acid composition of about 6.8 wt. %. As such a phosphoric acid range between 5 wt. % and 8 wt. % of 85% aqueous phosphoric acid solution may comprise between 4.25 wt. % and 6.8 wt. % phosphoric acid. Where possible solutions of composition constituents have been included in the examples.

One aspect or component of the barrier polishing composition is the use of one or more chelating agents to complex with the surface of the substrate to enhance the electrochemical dissolution process, or both. The chelating agents may also be used to buffer the polishing composition to maintain a desired pH level for processing a substrate. The chelating agents may also passivate or enhance the formation of a passivation layer on the substrate surface. Chelating agents may comprise three types of agents referred to as a first chelating agent, a second chelating agent, and an organic acid salts. The chelating agent component of the composition may be present at a concentration between about 0.1 wt. % and 25 wt. %, such as between about 4 wt. % and about 10 wt. % of the composition, and may vary based on the number and mount of the chelating agents described herein in the barrier polishing composition.

The composition may include any combination of the first chelating agent, the second chelating agent, or the organic salt. One embodiment of the composition includes at least a first chelating agent and a second chelating agent, with the first and second chelating agent being different from one another. Another embodiment of the composition includes a first chelating agent, a second chelating agent, and an organic acid salt being present. Another embodiment of the composition includes one or more chelating agents from the type of compounds of the first chelating agent. Another embodiment of the composition includes one or more chelating agents from the type of compounds of the second chelating agent. Another embodiment of the composition includes a plurality of chelating agents from each of the type of compounds of the first and second chelating agents respectively.

The first chelating agent comprises a molecule having a nitrogen containing functional group. Nitrogen containing function groups include amine functional groups, amide functional groups, pyridyl functional groups, and combinations thereof. Suitable first chelating agents may be free of a carboxylate functional group.

Examples of suitable first chelating agents having an amine or amide functional group can include compounds such as ethylenediamine (EDA), diethylenetriamine, diethylenetriamine derivatives, hexadiamine, amino acids, glycine, methylformamide, derivatives thereof, salts thereof or combinations thereof. Examples of suitable first chelating agents having a pyridyl group includes for example, 2,2′-dipyridyl, among others.

The chelating agent having nitrogen containing functional group may be in the composition at a concentration between about 0.1 wt. % and 15 wt. %, such as between about 0.2 wt. % and about 5 wt. % of the composition. For example, between about 3 wt. % and about 5 wt. % of ethylenediamine may be used as a chelating agent an amine or amide functional group.

The second chelating agent comprises a molecule having a carboxylate functional group (COOH—). The chelating agent having a carboxylate functional group include compounds having one or more functional groups selected from the group of carboxylate functional groups, dicarboxylate functional groups, tricarboxylate functional groups, or combinations thereof. Suitable second chelating agents may be free of a nitrogen containing functional group.

Examples of suitable second chelating agents having a carboxylate functional group include glycolic acid citric acid, tartaric acid, succinic acid, oxalic acid, or combinations thereof. Other suitable chelating agents having one or more carboxylate functional groups include acetic acid, adipic acid, butyric acid, capric acid, caproic acid, caprylic acid, glutaric acid, formaic acid, fumaric acid, lactic acid, lauric acid, malic acid, maleic acid, malonic acid, myristic acid, plamitic acid, phthalic acid, propionic acid, pyruvic acid, stearic acid, valeric acid, derivatives thereof, salts thereof or combinations thereof. The second chelating agent may further include a hydroxyl functional group (OH—). An example of a compound having a carboxylate functional group and a hydroxyl functional group includes glycolic acid, among others.

Alternatively, the second chelating agent may comprise a chelating agent having a carboxylate functional group and an amine or amide functional group, and salts thereof. Examples of suitable alternative second chelating agents include amino acids, such as glycine, and ethylenediaminetetraacetic acid (EDTA), and salts thereof, among others. Examples of salts include EDTA salts, such as sodium, potassium and calcium (e.g., Na₂EDTA, Na₄EDTA, K₄EDTA or Ca₂EDTA).

In a further alternative, the second chelating agent may comprise a chelating agent having a hydroxyl group and free of a carboxylate functional group. Suitable second chelating agents include ethylene glycol and derivatives thereof.

The second chelating agent may be present in the composition at a concentration between about 0.1 weight percent (wt. %) and about 10 wt. %, but preferably utilized between about 2 wt. % and about 8 wt. %.

An organic acid salt, which may also function as a third chelating agent, may be used in the barrier composition. The organic acid salt includes salts of compounds having a carboxylate functional group described herein, for example, ammonia and potassium salts thereof compounds having a carboxylate functional group. For example, suitable salts for an organic acid salt may include ammonium citrate, ammonium hydrogen citrate, potassium citrate, potassium hydrogen citrate, ammonium succinate, potassium succinate, ammonium oxalate, potassium oxalate, potassium tartrate, or combinations thereof. The organic acid salt may have multi-basic states, for example, citrates have mono-, di- and tri-basic states. The organic acid salt may be provided in salt form or be formed in combination of the second chelating agent with pH adjusting agent organic acid salt described herein. For example, the organic acid salt may include ammonium citrate, ammonium hydrogen citrate, ammonium succinate, ammonium oxalate, as a combination of citric, succinic, or oxalic acid and an ammonium hydroxide pH adjusting agent, and potassium citrate, potassium succinate, potassium oxalate, potassium tartrate, as a combination of citric, succinic, oxalic, or tartaric acid and a potassium hydroxide pH adjusting agent.

The organic acid salt may be present at a concentration between about 0.1 wt. % and about 15 wt % of the composition, for example, between about 0.1 wt. % and about 8 wt. % by volume or weight. For example, about 2 wt. % of ammonium hydrogen citrate may be used in the barrier polishing composition. The organic salt may also be added in solution or in a substantially pure form, for example, ammonium hydrogen citrate may be added in a 98% pure form.

Alternatively, the one or more chelating agents may comprise only one of the first, second, or third chelating agents described above for use in specific compositions. It has been observed that different finishes of the polishing surface may be achieved with the use of desired chelating agents with a composition of a desired pH level. For example, lactic acid or phthalic acid may be used under acidic media, the pH is less than 7, such as less than a pH of 5. For example, glycine or ethylene glycol may be used under natural media, which may be pH between about 6 and about 8. Ethylenediamine or 2,2′-dipyridyl may be used under a basic media, which is greater than a pH of 7, such as between about 7 and about 11.

The polishing composition may have a pH between about 2 and about 10, and preferably between a pH of about 3 and about 7. The pH may be established in the polishing composition by a balance of the chelating agents, or alternatively, one or more pH adjusting agents is preferably added to the polishing composition. The amount of pH adjusting agent can vary as the concentration of the other components is varied in different formulations, but in general the total solution may include up and about 70 wt. % of the one or more pH adjusting agents, but preferably between about 0.2% and about 25% by volume. Different compounds may provide different pH levels for a given concentration, for example, the composition may include between about 0.1% and about 10% by volume of a base, such as potassium hydroxide, ammonium hydroxide, sodium hydroxide or combinations thereof, providing the desired pH level. The pH adjusting agent may also be added in solution or in a substantially pure form, for example, potassium hydroxide may be added in a 45% aqueous potassium hydroxide solution.

The one or more pH adjusting agents may further be chosen from a class of organic acids, for example, carboxylic acids, such as acetic acid, citric acid, oxalic acid, phosphate-containing components including phosphoric acid, ammonium phosphates, potassium phosphates, and combinations thereof, or a combination thereof. Inorganic acids including phosphoric acid, sulfuric acid, hydrochloric, nitric acid, derivatives thereof and combinations thereof, may also be used as a pH adjusting agent in the polishing composition.

The balance or remainder of the polishing compositions described herein is a solvent, such as a polar solvent, including water, preferably deionized water. Other solvent may be used solely or in combination with water, such as organic solvents. Organic solvents include alcohols, such as isopropyl alcohol or glycols, ethers, such as diethyl ether, furans, such as tetrahydrofuran, hydrocarbons, such as pentane or heptane, aromatic hydrocarbons, such as benzene or toluene, halogenated solvents, such as methylene chloride or carbon tetrachloride, derivatives, thereof and combinations thereof.

Alternatively, the polishing composition may include one or more surface finish enhancing and/or removal rate enhancing materials. Additional materials that may be added include one or more activating agents, one or more etching inhibitors, one or more oxidizers, or combinations thereof.

In any of the embodiments described herein, the etching inhibitors can be added to reduce the etching, oxidation, or corrosion of conductive materials and improve surface finish by forming a passivation layer that minimizes the chemical interaction between the conductive material and the surrounding electrolyte. The layer of material formed by the etching inhibitors thus tends to suppress or minimize the electrochemical current from the substrate surface to limit electrochemical deposition and/or dissolution. The etching inhibitors are believe to reduce the etching rate of conductive materials, such as tungsten, and allow more selective removal of barrier materials, such as titanium and titanium nitride. The polishing composition may include between about 0.001 wt. % and about 5.0 wt. % etching inhibitor. The commonly preferred range being between about 0.1 wt. % and about 1 wt. %, for example, between about 0.2 wt. % and about 0.4 wt. %.

Etching inhibitors include corrosion inhibitors having one or more azole groups. Examples of organic compounds having azole groups include benzotriazole (BTA), mercaptobenzotriazole, 5-methyl-1-benzotriazole (TTA), and combinations thereof. Other suitable corrosion inhibitors include film forming agents that are cyclic compounds, for example, imidazole, benzimidazole, triazole, and combinations thereof. Derivatives of benzotriazole, imidazole, benzimidazole, triazole, with hydroxy, amino, imino, carboxy, mercapto, nitro and alkyl substituted groups may also be used as corrosion inhibitors. The corrosion inhibitor may also be added in solution or in a substantially pure form, for example, benzotriazole may be added in a 99% pure form. Other corrosion inhibitor includes urea and thiourea among others.

Alternatively, polymeric inhibitors, for non-limiting examples, polyalkylaryl ether phosphate, ammonium nonylphenol ethoxylate sulfate, polyacrylic acid polymers, such as polymethylacrylic acids, polycarboxylic acid, polycarboxylate copolymers, polyphosphate, or combinations thereof, may be used in replacement or conjunction with the etching inhibitors in an amount between about 0.002% and about 1.0% by volume or weight of the composition.

Other suitable polymeric inhibitors include ethylene imine (C₂H₅N) based polymeric materials, such as polyethylene imine (PEI) having a molecular weight between about 400 and about 1000000 comprising (—CH₂—CH₂—NH—) monomer units, ethylene glycol (C₂H₆O₂) based polymeric materials, such as polyethylene glycol (PEG) having a molecular weight between about 200 and about 100000 comprising (OCH₂CH₂)_{N} monomer units, or combinations thereof. Polyamine and polyimide polymeric material may also be used as polymeric inhibitors in the composition. Other suitable polymeric inhibitors include oxide polymers, such as, polypropylene oxide and ethylene oxide/propylene oxide co-polymer (EOPO), with a Molecular Weight range between about 200 and about 100000.

Additionally, the polymeric inhibitors may comprise polymers of heterocyclic compounds containing nitrogen and/or oxygen atoms, such as polymeric materials derived from monomers of pyridine, pyrole, furan, purine, or combinations thereof. The polymeric inhibitors may also include polymers with both linear and heterocyclic structural units containing nitrogen and/or oxygen atoms, such as a heterocyclic structural units and amine or ethylene imine structural units. The polymeric inhibitors may also include carbon containing functional groups or structural units, such as homocyclic compounds, such as benzyl or phenyl functional groups, and linear hydrocarbons suitable as structural units or as functional groups to the polymeric backbone. A mixture of the polymeric inhibitors described herein is also contemplated, such as a polymeric mixture of a heterocyclic polymer material and an amine or ethylene imine polymeric material (polyethylene imine). An example of a suitable polymeric inhibitor includes XP-1296 (also known as L-2001), containing a heterocyclic polymer/polyamine polymer, commercially available from Rohm and Hass Electronic Materials of Marlborough, Mass., and Compound S-900, commercially available from Enthone-OMI Inc. of New Haven, Conn.

The polymeric inhibitor may be present in the barrier composition in amounts ranging between about 0.001 wt. % and about 2 wt. %, such as between about 0.005 wt. % and about 1 wt. %, for example, between about 0.01 wt. % and about 0.5 wt. %. A polymeric inhibitor of 2000, 70000 or 750000 molecular weight polyethylene imine in a concentration of between about 0.025 wt. % and about 0.1 wt. % may be used in the composition. More than one polymeric inhibitor may be included in the residual polishing composition. Some polymeric inhibitor may be added the composition in a solution, for example, the residual polishing composition may include 0.5 wt. % PEI with a 2000 molecular weight of a 5% aqueous PEI solution and/or 0.5 wt. % XP-1296 (or XP tradename family of compounds from Rohm and Haas) with a 2000 molecular weight of a 10% aqueous XP-1296 solution. L-2001 has about <1% heterocyclic polymer/amine polymer solution.

Polymeric inhibitors may be in a dilute form manufacturing, for example, polyethylene imine may be added to a composition from a 50% polyethylene imine solution, so the concentration of the solution may be 0.025 wt. % and the actual polyethylene imine concentration would be about 0.0125 wt. %. Thus, the invention contemplates that the percentages of all of the components, including the polymeric inhibitors, reflect both dilute compounds provided from their manufacturing source as well as the actual present amount of the component.

In one embodiment of the polishing composition, one or more activating agents may be introduced into the polishing composition to improve the removal rate of the barrier materials, such as titanium or titanium nitride, and/or improve the selectivity (i.e., increased relative removal rate between two materials or increased removal rate ratio between a first and second materials) of the barrier materials to the conductive materials and/or the dielectric materials used in forming features on the substrate surface.

While the barrier polishing composition herein may be describe as an abrasive free composition, abrasive particles as one type of activating agent may be used in the barrier polishing composition. The addition of abrasive particles to the polishing composition can allow the final polished surface to achieve a surface roughness of that comparable with a conventional CMP process even at low polishing article pressures. Surface finish, or surface roughness, has been shown to have an effect on device yield and post polishing surface defects. Abrasive particles may comprise up and about 30 wt. % of the polishing composition during processing. A concentration between about 0.001 wt. % and about 5 wt. % of abrasive particles may be used in the polishing composition.

Suitable abrasives particles include inorganic abrasives, polymeric abrasives, and combinations thereof. Inorganic abrasive particles that may be used in the electrolyte include, but are not limited to, silica, alumina, zirconium oxide, titanium oxide, cerium oxide, germania, or any other abrasives of metal oxides, known or unknown. For example, colloidal silica may be positively activated, such as with an alumina modification. The typical abrasive particle size used in one embodiment of the current invention is generally between about 1 nm and about 1,000 nm, preferably between about 10 nm and about 100 nm. Generally, suitable inorganic abrasives have a Mohs hardness of greater than 6, although the invention contemplates the use of abrasives having a lower Mohs hardness value.

The polymer abrasives described herein may also be referred to as “organic polymer particle abrasives”, “organic abrasives” or “organic particles.” The polymeric abrasives may comprise abrasive polymeric materials. Examples of polymeric abrasives materials include polymethylmethacrylate, polymethyl acrylate, polystyrene, polymethacrylonitrile, and combinations thereof.

The polymeric abrasives may have a Hardness Shore D of between about 60 and about 80, but can be modified to have greater or lesser hardness value. The softer polymeric abrasive particles can help reduce friction between a polishing article and substrate and may result in a reduction in the number and the severity of scratches and other surface defects as compared to inorganic particles. A harder polymeric abrasive particle may provide improved polishing performance, removal rate and surface finish as compared to softer materials.

The hardness of the polymer abrasives can be varied by controlling the extent of polymeric cross-linking in the abrasives, for example, a higher degree of cross-linking produces a greater hardness of polymer and, thus, abrasive. The polymeric abrasives are typically formed as spherical shaped beads having an average diameter between about 0.1 micron and about 20 microns or less.

The polymeric abrasives may be modified to have functional groups, e.g., one or more functional groups, that have an affinity for, i.e., can bind to, the conductive material or conductive material ions at the surface of the substrate, thereby facilitating the Ecmp removal of material from the surface of a substrate. For example, the organic polymer particles can be modified to have an amine group, a carboxylate group, a pyridine group, a hydroxide group, ligands with a high affinity for desired removal materials, or combinations thereof, to bind the removed materials as substitutes for or in addition to the chemically active agents in the polishing composition, such as the chelating agents or etching inhibitors. The substrate surface material, may be in any oxidation state, such as 0, 1+, 2+, 3+ and 4+, such as for titanium oxidation states, and further up to 5+for tantalum oxidation states, before, during or after ligating with a functional group. The functional groups can bind to the metal material(s) on the substrate surface to help improve the uniformity and surface finish of the substrate surface.

Additionally, the polymeric abrasives have desirable chemical properties, for example, the polymer abrasives are stable over a broad pH range and are not prone to aggregating to each other, which allow the polymeric abrasives to be used with reduced or no surfactant or no dispersing agent in the composition.

Alternatively, inorganic particles coated with the polymeric materials described herein may also be used with the polishing composition. It is within the scope of the current invention for the polishing composition to contain polymeric abrasives, inorganic abrasives, the polymeric coated inorganic abrasives, and any combination thereof depending on the desired polishing performance and results.

Another activating agent may be ions of at least one transition metal. The ion of at least one transitional metal may be derived from metal salts, such as copper salts, and are added to the composition to form a complex with the one or more chelating agents. The resulting complex improves removal of residual copper containing material from the substrate surface. Examples of suitable copper salts include copper sulfate, copper fluoborate, copper gluconate, copper sulfamate, copper sulfonate, copper pyrophosphate, copper chloride, copper cyanide, and combinations thereof. The copper salt can comprise a concentration between about 0.005 weight percent (wt. %) and about 1.0 wt. % of the CMP composition. Alternatively, the copper salts may be present in the CMP composition at a concentration between about 0.05 wt. % and about 0.2 wt. % of the CMP composition.

While the barrier polishing composition may be described as an oxidizer free composition, one or more oxidizers may be used herein to enhance the removal or removal rate of the conductive material from the substrate surface. The oxidizer can be present in the polishing composition in an amount ranging between about 0.01% and about 90% by volume or weight, for example, between about 0.1% and about 20% by volume or weight. In an embodiment of the polishing composition, between about 0.1% and about 15% by volume or weight of hydrogen peroxide is present in the polishing composition. The oxidizer may be added to the composition in a solution, such as a 30% aqueous hydrogen peroxide solution or a 40% aqueous hydrogen peroxide solution. In one embodiment, the oxidizer is added to the rest of the polishing composition just prior to beginning the Ecmp process.

Examples of suitable oxidizers include peroxy compounds, e.g., compounds that may disassociate through hydroxy radicals, such as hydrogen peroxide and its adducts including urea hydrogen peroxide, percarbonates, and organic peroxides including, for example, alkyl peroxides, cyclical or aryl peroxides, benzoyl peroxide, peracetic acid, and ditertbutyl peroxide. Sulfates and sulfate derivatives, such as monopersulfates and dipersulfates may also be used including for example, ammonium peroxydisulfate, potassium peroxydisulfate, ammonium persulfate, and potassium persulfate. Salts of peroxy compounds, such as sodium percarbonate and sodium peroxide may also be used.

The oxidizing agent can also be an inorganic compound or a compound containing an element in its highest oxidation state. Examples of inorganic compounds and compounds containing an element in its highest oxidation state include but are not limited to periodic acid, periodate salts, perbromic acid, perbromate salts, perchloric acid, perchloric salts, perbonic acid, nitrate salts (such as cerium nitrate, iron nitrate, ammonium nitrate), ferrates, perborate salts and permanganates. Other oxidizing agents include bromates, chlorates, chromates, iodates, iodic acid, and cerium (IV) compounds such as ammonium cerium nitrate.

The polishing composition may include one or more additive compounds. Additive compounds include electrolyte additives including, but not limited to, suppressors, enhancers, levelers, brighteners, stabilizers, and stripping agents to improve the effectiveness of the polishing composition in polishing of the substrate surface. For example, certain additives may decrease the ionization rate of the matal atoms, thereby inhibiting the dissolution process, whereas other additives may provide a finished, shiny substrate surface. The additives may be present in the polishing composition in concentrations up and about 15% by weight or volume, and may vary based upon the desired result after polishing.

Further examples of additives to the polishing composition are more fully described in U.S. patent application Ser. No. 10/141,459, filed on May 7, 2002, which is incorporated by reference herein to the extent not inconsistent with the claimed aspects and disclosure herein.

Polishing compositions utilized during embodiments herein are advantageous for Ecmp processes in removing barrier materials. Generally, Ecmp solutions are much more conductive than traditional CMP solutions. The Ecmp solutions have a conductivity of about 10 millisiemens (ms) or higher, while traditional CMP solutions have a conductivity between about 3 ms and about 5 ms. The conductivity of the Ecmp solutions greatly influences that rate at which the Ecmp process advances, i.e., more conductive solutions have a faster material removal rate. For removing barrier material, the Ecmp solution has a conductivity of about 10 ms or higher, preferably in a range between about 15 ms and about 60 ms.

Tungsten Polishing Compositions (Incorporate by Reference)

For polishing the tungsten material, the bulk polishing composition includes one or more acid based electrolyte systems, a first chelating agent including an organic salt, a pH adjusting agent to provide a pH between about 2 and about 10 and a solvent. The polishing composition may further include a second chelating agent having one or more functional groups selected from the group consisting of amine groups, amide groups, and combinations thereof. The one or more acid based electrolyte systems preferably include two acid based electrolyte systems, for example, a sulfuric acid based electrolyte system and a phosphoric acid based electrolyte system. The bulk polishing composition may optionally include one or more corrosion inhibitors or a polishing enhancing material, such as abrasive particles. While the compositions described herein are oxidizer free compositions, the invention contemplates the use of oxidizers as a polishing enhancing material that may further be used with an abrasive material. It is believed that the bulk and residue polishing compositions described herein improve the effective removal rate of materials, such as tungsten, from the substrate surface during Ecmp, with a reduction in planarization type defects and yielding a smoother substrate surface. The embodiments of the compositions may be used in a one-step or two-step polishing process. Components of the tungsten compositions may also be added in solution as described above with regard to the barrier polishing composition.

Although the polishing compositions are particularly useful for removing tungsten. It is believed that the polishing compositions may also remove other conductive materials, such as aluminum, platinum, copper, titanium, titanium nitride, tantalum, tantalum nitride, cobalt, gold, silver, ruthenium and combinations thereof. Mechanical abrasion, such as from contact with the conductive pad 203 and/or abrasives, and/or anodic dissolution from an applied electrical bias, may be used to improve planarity and improve removal rate of these conductive materials.

The sulfuric acid based electrolyte system includes, for example, electrolytes and compounds having a sulfate group (SO₄²⁻), such as sulfuric acid (H₂SO₄), and/or derivative salts thereof including, for example, ammonium hydrogen sulfate (NH₄HSO₄), ammonium sulfate, potassium sulfate, tungsten sulfate, or combinations thereof, of which sulfuric acid is preferred. Derivative salts may include ammonium (NH₄⁺), sodium (Na⁺), tetramethyl ammonium (Me₄N⁺, potassium (K⁺) salts, or combinations thereof, among others.

The phosphoric acid based electrolyte system includes, for example, electrolytes and compounds having a phosphate group (PO₄³⁻), such as, phosphoric acid, and/or derivative salts thereof including, for example, phosphate (MₓH₍₃₋ₓ₎PO₄) (x=1, 2, 3), with M including ammonium (NH₄⁺), sodium (Na⁺), tetramethyl ammonium (Me₄N+) or potassium (K⁺) salts, tungsten phosphate, ammonium dihydrogen phosphate ((NH₄)H₂PO₄), diammonium hydrogen phosphate ((NH₄)₂HPO₄), and combinations thereof, of which phosphoric acid is preferred. Alternatively, an acetic acid based electrolytic, including acetic acid and/or derivative salts, or a salicylic acid based electrolyte, including salicylic acid and/or derivative salts, may be used in place of the phosphoric acid based electrolyte system. The acid based electrolyte systems described herein may also buffer the composition to maintain a desired pH level for processing a substrate. The invention also contemplates that conventional electrolytes known and unknown may also be used in forming the composition described herein using the processes described herein.

The sulfuric acid based electrolyte system and phosphoric acid based electrolyte system may respectively, include between about 0.1 and about 30 percent by weight (wt. %) or volume (vol %) of the total composition of solution to provide suitable conductivity for practicing the processes described herein. Acid electrolyte concentrations between about 0.2 vol % and about 5 vol %, such as about 0.5 vol % and about 3 vol %, for example, between about 1 vol % and about 3 vol %, may be used in the composition. The respective acid electrolyte compositions may also vary between polishing compositions. For example in a first composition, the acid electrolyte may comprises between about 1.5 vol % and about 3 vol % sulfuric acid and between about 0.2 vol % and about 3 vol % phosphoric acid for bulk metal removal and in a second composition, between about 1 vol % and about 2 vol % vol % sulfuric acid and between about 0.2 vol % and about 2 vol % phosphoric acid for residual metal removal. The invention contemplates embodiments of the composition including a second composition having a sulfuric acid and/or phosphoric acid concentration less than the first composition.

One aspect or component of the present invention is the use of one or more chelating agents to complex with the surface of the substrate to enhance the electrochemical dissolution process. In any of the embodiments described herein, the chelating agents can bind to ions of a conductive material, such as tungsten ions, increase the removal rate of metal materials and/or improve polishing performance. The chelating agents may also be used to buffer the polishing composition to maintain a desired pH level for processing a substrate.

One suitable category of chelating agents includes inorganic or organic acid salts. Salts of other organic acids which may be suitable are salts of compounds having one or more functional groups selected from the group of carboxylate groups, dicarboxylate groups, tricarboxylate groups, a mixture of hydroxyl and carboxylate groups, and combinations thereof. The metal materials for removal, such as tungsten, may be in any oxidation state before, during or after ligating with a functional group. The functional groups can bind the metal materials created on the substrate surface during processing and remove the metal materials from the substrate surface.

Examples of suitable inorganic or organic acid salts include ammonium and potassium salts of organic acids, such as ammonium oxalate, ammonium citrate, ammonium succinate, monobasic potassium citrate, dibasic potassium citrate, tribasic potassium citrate, potassium tartarate, ammonium tartarate, potassium succinate, potassium oxalate, and combinations thereof. Examples of suitable acids for use in forming the salts of the chelating agent that having one or more carboxylate groups include citric acid, tartaric acid, succinic acid, oxalic acid, acetic acid, adipic acid, butyric acid, capric acid, caproic acid, caprylic acid, glutaric acid, glycolic acid, formaic acid, fumaric acid, lactic acid, lauric acid, malic acid, maleic acid, malonic acid, myristic acid, plamitic acid, phthalic acid, propionic acid, pyruvic acid, stearic acid, valeric acid, and combinations thereof.

The polishing composition may include one or more inorganic or organic salts at a concentration between about 0.1 wt. % and about 15 wt. % of the composition, for example, between about 0.2 wt. % and about 5%, such as between about 1 wt. % and about 3 wt. %. For example, between about 0.5 wt. % and about 2 wt. % by weight of ammonium citrate may be used in the polishing composition.

Alternatively, a second chelating agent having one or more functional groups selected from the group of amine groups, amide groups, hydroxyl groups, and combinations thereof, may be used in the composition. Preferred functional groups are selected from the group consisting of amine groups, amide groups, hydroxyl groups, and combinations thereof, do not have acidic functional groups such as carboxylate groups, dicarboxylate groups, tricarboxylate groups, and combinations thereof. The polishing composition may include one or more chelating agents having one or more functional groups selected from the group of amine groups, amide groups, hydroxyl groups, and combinations thereof, at a concentration between about 0.1% and about 5% by volume or weight, but preferably utilized between about 1% and about 3% by volume or weight, for example about 2% by volume or weight. For example, between about 2 vol % and about 3 vol % of ethylenediamine may be used as a chelating agent. Further examples of suitable chelating agents include compounds having one or more amine and amide functional groups, such as ethylenediamine, and derivatives thereof including diethylenetriamine, hexadiamine, amino acids, ethylenediaminetetraacetic acid, methylformamide, or combinations thereof.

The solution may include one or more pH adjusting agents to achieve a pH between about 2 and about 10. The amount of pH adjusting agent can vary as the concentration of the other components is varied in different formulations, but in general the total solution may include up to about 70 wt. % of the one or more pH adjusting agents, but preferably between about 0.2 wt. % and about 25 wt. %. Different compounds may provide different pH levels for a given concentration, for example, the composition may include between about 0.1 wt. % and about 10 wt. % of a base, such as potassium hydroxide, sodium hydroxide, ammonium hydroxide, tetramethyl ammonium hydroxide (TMAH), or combinations thereof, to provide the desired pH level. The pH adjusting agent may also be added in solution or in a substantially pure form, for example, potassium hydroxide may be added in a 45% aqueous potassium hydroxide solution. The one or more pH adjusting agents can also be chosen from a class of inorganic acids including hydrochloric acid, sulfuric acid, and phosphoric acid may also be used in the polishing composition.

Typically, the amount of pH adjusting agents in the polishing composition will vary depending on the desired pH range for components having different constituents for various polishing processes. For example, in a bulk tungsten polishing process, the amount of pH adjusting agents may be adjusted to produce pH levels between about 6 and about 10. The pH in one embodiment of the bulk tungsten removal composition is a neutral or basic pH in the range between about 7 and about 9, for example, a basic solution greater than 7 and less than or equal to about 9, such as between about 8 and about 9.

The compositions included herein may include between about 1 vol % and about 5 vol % of sulfuric acid, between about 0.2 vol % and about 5 vol % of phosphoric acid, between about 1 wt. % and about 5 wt. % of ammonium citrate, alternatively between about 0.5 wt. % and about 5 wt. % of ethylenediamine, a pH adjusting agent to provide a pH between about 6 and about 10, and deionized water, such as a composition including between about 1 vol % and about 3 vol % of sulfuric acid, between about 0.2 vol % and about 3 vol % of phosphoric acid, between about 1 wt. % and about 3 wt. % of ammonium citrate, between about 1 wt. % and about 3 wt. % of ethylenediamine, between about 4 vol % and about 10 vol % of potassium hydroxide to provide a pH between about 7 and about 9, and deionized water. Another embodiment of the composition may include between about 0.2 vol % and about 5 vol % of sulfuric acid, between about 0.2 vol % and about 5 vol % of phosphoric acid, between about 0.1 wt. % and about 5 wt. % of ammonium citrate, a pH adjusting agent to provide a pH between about 2 and about 8, such as between about 3 and about 8, and deionized water. Another embodiment of the composition may include between about 0.5 vol % and about 2 vol % of sulfuric acid, between about 0.5 vol % and about 2 vol % of phosphoric acid, between about 0.5 wt. % and about 2 wt. % of ammonium citrate, potassium hydroxide to provide a pH between about 6 and about 7, and deionized water.

In any of the embodiments described herein, the preferred polishing compositions described herein are oxidizer-free compositions, for example, compositions free of oxidizers and oxidizing agents. Examples of oxidizers and oxidizing agents include, without limitation, hydrogen peroxide, ammonium persulfate, potassium iodate, potassium permnanganate, and cerium compounds including ceric nitrate, ceric ammonium nitrate, bromates, chlorates, chromates, iodic acid, among others.

Alternatively, the polishing compositions may include an oxidizing compound. Examples of suitable oxidizer compounds beyond those listed herein are nitrate compounds including ferric nitrate, nitric acid, and potassium nitrate. In one alternative embodiment of the compositions described herein, a nitric acid based electrolyte system, such as electrolytes and compounds having a nitrate group (NO₃¹⁻), such as nitric acid (HNO₃), and/or derivative salts thereof, including ferric nitrate (Fe(NO₃)₃), may be used in place of the sulfuric acid based electrolyte.

In any of the embodiments described herein, etching inhibitors, for example, corrosion inhibitors, can be added to reduce the oxidation or corrosion of metal surfaces, by chemical or electrical means, by forming a layer of material which minimizes the chemical interaction between the substrate surface and the surrounding electrolyte. The layer of material formed by the inhibitors may suppress or minimize the electrochemical current from the substrate surface to limit electrochemical deposition and/or dissolution.

Etching inhibitors of tungsten inhibits the conversion of solid tungsten into soluble tungsten compounds while at the same time allowing the composition to convert tungsten to a soft oxidized film that can be evenly removed by abrasion. Useful etching inhibitors for tungsten include compounds having nitrogen containing functional groups such as nitrogen containing heteroycles, alkyl ammonium ions, amino alkyls, amino acids. Etching inhibitors include corrosion inhibitors, such as compounds including nitrogen containing heterocycle functional groups, for example, 2,3,5-trimethylpyrazine, 2-ethyl-3,5-dimethylpyrazine, quinoxaline, acetyl pyrrole, pyridazine, histidine, pyrazine, benzimidazole and mixtures thereof.

The term “alkyl ammonium ion” as used herein refers to nitrogen containing compounds having functional groups that can produce alkyl ammonium ions in aqueous solutions. The level of alkylammonium ions produced in aqueous solutions including compounds with nitrogen containing functional groups is a function of solution pH and the compound or compounds chosen. Examples of nitrogen containing functional group corrosion inhibitors that produce inhibitory amounts of alkyl ammonium ion functional groups at aqueous solution with a pH less than 9.0 include isostearylethylimididonium, cetyltrimethyl ammonium hydroxide, alkaterge E (2-heptadecenyl-4-ethyl-2 oxazoline 4-methanol), aliquat 336 (tricaprylmethyl ammonium chloride), nuospet 101 (4,4 dimethyloxazolidine), tetrabutylammonium hydroxide, dodecylamine, tetramethylammonium hydroxide, derivatives thereof, and mixtures thereof.

Useful amino alkyl corrosion inhibitors include, for example, aminopropylsilanol, aminopropylsiloxane, dodecylamine, mixtures thereof, and synthetic and naturally occurring amino acids including, for example, lysine, tyrosine, glitamine, glutamic acid, glycine, cystine and glycine.

A preferred alkyl ammonium ion functional group containing inhibitor of tungsten etching is SILQUEST A-1106 silane, manufactured by OSI Specialties, Inc. SILQUEST A-1106 is a mixture of approximately 60 weight percent (wt. %) water, approximately 30 wt. % aminopropylsiloxane, and approximately 10 wt. % aminopropylsilanol. The aminopropylsiloxane and aminopropylsilanol each form an inhibiting amount of corresponding alkylammonium ions at a pH less than about 7. A most preferred amino alkyl corrosion inhibitor is glycine (aminoacetic acid).

Examples of suitable inhibitors of tungsten etching include halogen derivatives of alkyl ammonium ions, such as dodecyltrimethylammonium bromide, imines, such as polyethyleneimine, carboxy acid derivatives, such as calcium acetate, organosilicon compounds, such as di(mercaptopropyl)dimethoxylsilane, and polyacrylates, such as polymethylacrylate.

The inhibitor of tungsten etching should be present in the composition of this invention in amounts ranging from about 0.001 wt. % to about 2.0 wt. % and preferably from about 0.005 wt. % to about 1.0 wt. %, and most preferably from about 0.01 wt. % to about 0.10 wt. %. The inhibitors of tungsten etching are effective at composition with a pH up to about 9.0. It is preferred that the compositions of this invention have a pH of less than about 7.0 and most preferably less than about 6.5.

Other inhibitors may include between about 0.001% and about 5.0% by weight of the organic compound from one or more azole groups. The commonly preferred range being between about 0.2% and about 0.4% by weight. Examples of organic compounds having azole groups include benzotriazole, mercaptobenzotriazole, 5-methyl-1-benzotriazole, and combinations thereof. Other suitable corrosion inhibitors include film forming agents that are cyclic compounds, for example, imidazole, benzimidazole, triazole, and combinations thereof. Derivatives of benzotriazole, imidazole, benzimidazole, triazole, with hydroxy, amino, imino, carboxy, mercapto, nitro and alkyl substituted groups may also be used as corrosion inhibitors. Other corrosion inhibitors include urea and thiourea among others.

Alternatively, acid derivative polymeric inhibitors, for non-limiting examples, polyalkylaryl ether phosphate or ammonium nonylphenol ethoxylate sulfate, may be used in replacement or conjunction with azole containing inhibitors in an amount between about 0.002% and about 1.0% by volume or weight of the composition. Other suitable polymeric inhibitors including polyethylene imine (PEI) polyethylene glycol (PEG), polyamine polymeric material, polyimide polymeric material, oxide polymers, such as, polypropylene oxide and ethylene oxide/propylene oxide co-polymer (EOPO), or combinations thereof, as described above in the barrier polishing composition may also be used in the bulk tungsten polishing composition.

While the polishing compositions described above are free of oxidizers (oxidizer-free) and/or abrasive particles (abrasive-free), the polishing composition contemplates including one or more surface finish enhancing and/or removal rate enhancing materials including abrasive particles, one or more oxidizers, and combinations thereof. One or more surfactants may be used in the polishing composition to increase the dissolution or solubility of materials, such as metals and metal ions or by-products produced during processing, reduce any potential agglomeration of abrasive particles in the polishing composition, improve chemical stability, and reduce decomposition of components of the polishing composition. Suitable oxidizers and abrasives are described in co-pending U.S. patent application Ser. No. 10/378,097, filed on Feb. 26, 2004, which is incorporated by reference herein to the extent not inconsistent with the claimed aspects and disclosure herein.

Alternatively, the polishing composition may further include electrolyte additives including suppressors, enhancers, levelers, brighteners, stabilizers, and stripping agents to improve the effectiveness of the polishing composition in polishing of the substrate surface. For example, certain additives may decrease the ionization rate of the metal atoms, thereby inhibiting the dissolution process, whereas other additives may provide a finished, shiny substrate surface. The additives may be present in the polishing composition in concentrations up to about 15% by weight or volume, and may vary based upon the desired result after polishing.

Further examples of additives to the polishing composition are more fully described in U.S. patent application Ser. No. 10/141,459, filed on May 7, 2002, which is incorporated by reference herein to the extent not inconsistent with the claimed aspects and disclosure herein.

The balance or remainder of the bulk polishing composition described above is a solvent, such as a polar solvent, including water, preferably deionized water. Other solvents may include, for example, organic solvents, such as alcohols or glycols, and in some embodiments may be combined with water. The amount of solvent may be used to control the concentrations of the various components in the composition. For example, the electrolyte may be concentrated up to three times as concentrated as described herein and then diluted with the solvent prior to use of diluted at the processing station as described herein.

Generally, the residue polishing composition including one or more inorganic acids, a pH adjusting agent, a chelating agent, a passivating polymeric material, a pH between about 5 and about 10, and a solvent. The one or more inorganic acids provide for two acid based electrolyte systems, for example, a sulfuric acid based electrolyte system and a phosphoric acid based electrolyte system. Embodiments of the polishing composition may be used for polishing bulk and/or residual materials. The polishing composition may optionally include a polishing enhancing material, such as abrasive particles. While the compositions described herein are oxidizer free compositions, the invention contemplates the use of oxidizers as a polishing enhancing material that may further be used with an abrasive material. It is believed that the polishing compositions described herein improve the effective removal rate of materials, such as tungsten, from the substrate surface during Ecmp, with a reduction in planarization type defects and yielding a smoother substrate surface. The embodiments of the compositions may be used in a one-step or two-step polishing process. The sulfuric acid based electrolyte system includes, for example, electrolytes and compounds having a sulfate group (SO₄²⁻), such as sulfuric acid (H₂SO₄), and/or derivative salts thereof including, for example, ammonium hydrogen sulfate (NH₄HSO₄), ammonium sulfate, potassium sulfate, tungsten sulfate, or combinations thereof, of which sulfuric acid is preferred. Derivative salts may include ammonium (NH₄₊), sodium (Na⁺), tetramethyl ammonium (Me₄N⁺, potassium (K⁺) salts, or combinations thereof, among others.

The phosphoric acid based electrolyte system includes, for example, electrolytes and compounds having a phosphate group (PO₄³⁻), such as, phosphoric acid, and/or derivative salts thereof including, for example, phosphate (MₓH₍₃₋ₓ₎PO₄) (x=1, 2, 3), with M including ammonium (NH₄₊), sodium (Na⁺), tetramethyl ammonium (Me₄N⁺) or potassium (K⁺) salts, tungsten phosphate, ammonium dihydrogen phosphate ((NH₄)H₂PO₄), diammonium hydrogen phosphate ((NH₄)₂HPO₄), and combinations thereof, of which phosphoric acid is preferred. Alternatively, an acetic acid based electrolytic, including acetic acid and/or derivative salts, or a salicylic acid based electrolyte, including salicylic acid and/or derivative salts, may be used in place of the phosphoric acid based electrolyte system. The acid based electrolyte systems described herein may also buffer the composition to maintain a desired pH level for processing a substrate. The invention also contemplates that conventional electrolytes known and unknown may also be used in forming the composition described herein using the processes described herein.

The sulfuric acid based electrolyte system and phosphoric acid based electrolyte system may respectively, include between about 0.1 and about 30 percent by weight (wt. %) or volume (vol %) of the total composition of solution to provide suitable conductivity for practicing the processes described herein. Acid electrolyte concentrations between about 0.2 vol % and about 2 vol %, such as about 0.5 vol % and about 1.5 vol %, may be used in the composition. The respective acid electrolyte compositions may also vary between polishing compositions. The invention contemplates embodiments of the composition including a second composition having a sulfuric acid and/or phosphoric acid concentration less than the first composition.

One aspect or component of the present invention is the use of one or more chelating agents to complex with the surface of the substrate to enhance the electrochemical dissolution process. In any of the embodiments described herein, the chelating agents can bind to ions of a conductive material, such as tungsten ions, increase the removal rate of metal materials and/or improve polishing performance. The chelating agents may also be used to buffer the polishing composition to maintain a desired pH level for processing a substrate.

One suitable category of chelating agents includes inorganic or organic acid salts. Salts of other organic acids which may be suitable are salts of compounds having one or more functional groups selected from the group of carboxylate groups, dicarboxylate groups, tricarboxylate groups, a mixture of hydroxyl and carboxylate groups, and combinations thereof. The metal materials for removal, such as tungsten, may be in any oxidation state before, during or after ligating with a functional group. The functional groups can bind the metal materials created on the substrate surface during processing and remove the metal materials from the substrate surface.

Examples of suitable inorganic or organic acid salts include ammonium and potassium salts of organic acids, such as ammonium oxalate, ammonium citrate, ammonium succinate, monobasic potassium citrate, dibasic potassium citrate, tribasic potassium citrate, potassium tartarate, ammonium tartarate, potassium succinate, potassium oxalate, and combinations thereof. Examples of suitable acids for use in forming the salts of the chelating agent that having one or more carboxylate groups include citric acid, tartaric acid, succinic acid, oxalic acid, acetic acid, adipic acid, butyric acid, capric acid, caproic acid, caprylic acid, glutaric acid, glycolic acid, formaic acid, fumaric acid, lactic acid, lauric acid, malic acid, maleic acid, malonic acid, myristic acid, plamitic acid, phthalic acid, propionic acid, pyruvic acid, stearic acid, valeric acid, and combinations thereof.

The polishing composition may include one or more inorganic or organic salts at a concentration between about 0.1 wt. % and about 15 wt. % by volume or weight of the composition, for example, between about 0.1% and about 2% by volume or weight, such as between about 0.5 wt. % and about 1 wt. % by volume or weight. For example, about 0.5 wt. % of ammonium citrate may be used in the polishing composition.

Alternatively, a second chelating agent having one or more functional groups selected from the group of amine groups, amide groups, hydroxyl groups, and combinations thereof, may be used in the composition. Preferred functional groups are selected from the group consisting of amine groups, amide groups, hydroxyl groups, and combinations thereof, do not have acidic functional groups such as carboxylate groups, dicarboxylate groups, tricarboxylate groups, and combinations thereof. The polishing composition may include one or more chelating agents having one or more functional groups selected from the group of amine groups, amide groups, hydroxyl groups, and combinations thereof, at a concentration between about 0.1% and about 5% by volume or weight, but preferably utilized between about 1% and about 3% by volume or weight, for example about 2% by volume or weight. For example, between about 2 vol % and about 3 vol % of ethylenediamine may be used as a chelating agent. Further examples of suitable chelating agents include compounds having one or more amine and amide functional groups, such as ethylenediamine, and derivatives thereof including diethylenetriamine, hexadiamine, amino acids, ethylenediaminetetraacetic acid, methylformamide, or combinations thereof.

The solution may include one or more pH adjusting agents to achieve a pH between about 2 and about 10. The amount of pH adjusting agent can vary as the concentration of the other components is varied in different formulations, but in general the total solution may include up to about 70 wt. % of the one or more pH adjusting agents, but preferably between about 0.2 wt. % and about 25 wt. %, such as between about 3 wt. % and about 10 wt. %. Different compounds may provide different pH levels for a given concentration, for example, the composition may include between about 4 wt. % and about 7 wt. % of a base, such as potassium hydroxide, sodium hydroxide, ammonium hydroxide, tetramethyl ammonium hydroxide (TMAH), or combinations thereof, to provide the desired pH level. The one or more pH adjusting agents can be chosen from a class of organic acids, for example, carboxylic acids, such as acetic acid, citric acid, oxalic acid, phosphate-containing components including phosphoric acid, ammonium phosphates, potassium phosphates, and combinations thereof, or a combination thereof. Inorganic acids including hydrochloric acid, sulfuric acid, and phosphoric acid may also be used in the polishing composition.

Typically, the amount of pH adjusting agents in the polishing composition will vary depending on the desired pH range for components having different constituents for various polishing processes. For example, in a residue tungsten polishing process, the amount of pH adjusting agents may be adjusted to produce pH levels between about 5 and about 10. The pH in one embodiment of the residue tungsten removal composition is a neutral or acidic pH in the range between about 5 and about 7, for example, 6.

The residue composition includes polymeric inhibitors, which by chemical or physical means, form a layer of material which minimizes the chemical interaction between the substrate surface and the surrounding electrolyte. The layer of material formed by the inhibitors may suppress or minimize the electrochemical current from the substrate surface to limit electrochemical deposition and/or dissolution.

Other suitable polymeric inhibitors include ethylene imine (C₂H₅N) based polymeric materials, such as polyethylene imine (PEI) having a molecular weight between about 400 and about 1000000 comprising (—CH₂—CH₂—NH—) monomer units, ethylene glycol (C₂H₆O₂) based polymeric materials, such as polyethylene glycol (PEG) having a molecular weight between about 200 and about 100000 comprising (OCH₂CH₂)N monomer units, or combinations thereof. Polyamine and polyimide polymeric material may also be used as polymeric inhibitors in the composition. Other suitable polymeric inhibitors include oxide polymers, such as, polypropylene oxide and ethylene oxide/propylene oxide co-polymer (EOPO), with a Molecular Weight range between about 200 and about 100000.

Additionally, the polymeric inhibitors may comprise polymers of heterocyclic compounds containing nitrogen and/or oxygen atoms, such as polymeric materials derived from monomers of pyridine, pyrole, furan, purine, or combinations thereof. The polymeric inhibitors may also include polymers with both linear and heterocyclic structural units containing nitrogen and/or oxygen atoms, such as a heterocyclic structural units and amine or ethylene imine structural units. The polymeric inhibitors may also include carbon containing functional groups or structural units, such as homocyclic compounds, such as benzyl or phenyl functional groups, and linear hydrocarbons suitable as structural units or as functional groups to the polymeric backbone. A mixture of the polymeric inhibitors described herein is also contemplated, such as a polymeric mixture of a heterocyclic polymer material and an amine or ethylene imine polymeric material (polyethylene imine). An example of a suitable polymeric inhibitor includes XP-1296 (also known as L-2001), containing a heterocyclic polymer/polyamine polymer, commercially available from Rohm and Hass Electronic Materials of Marlborough, Mass., and Compound S-900, commercially available from Enthone-OMI Inc. of New Haven, Conn.

The polymeric inhibitor may be present in the residual composition of this invention in amounts ranging between about 0.001 wt. % and about 2 wt. %, such as between about 0.005 wt. % and about 1 wt. %, for example, between about 0.01 wt. % and about 0.5 wt. %. A polymeric inhibitor of 2000, 70000 or 750000 molecular weight polyethylene imine in a concentration of between about 0.025 wt. % and about 0.1 wt. % may be used in the composition. More than one polymeric inhibitor may be included in the residual polishing composition. Some polymeric inhibitor may be added the composition in a solution, for example, the residual polishing composition may include 0.5 wt. % PEI with a 2000 molecular weight of a 5% aqueous PEI solution and/or 0.5 wt. % XP-1296 (or XP tradename family of compounds from Rohm and Haas) with a 2000 molecular weight of a 10% aqueous XP-1296 solution.

Polymeric inhibitors may be in a dilute form manufacturing, for example, polyethylene imine may be added to a composition from a 50% polyethylene imine solution, so the concentration of the solution may be 0.025 wt. % and the actual polyethylene imine concentration would be about 0.0125 wt. %. Thus, the invention contemplates that the percentages of all of the components, including the polymeric inhibitors, reflect both dilute compounds provided from their manufacturing source as well as the actual present amount of the component. For example, 6% phosphoric acid may also be present as 5.1%, or 6% of the 85% phosphoric acid solution available from phosphoric acid manufacturers. Where possible, the actual amount of the component of the composition has been provided.

Optionally, additional inhibitors may include between about 0.001% and about 5.0% by weight of the organic compound from one or more azole groups. The commonly preferred range being between about 0.2% and about 0.4% by weight. Examples of organic compounds having azole groups include benzotriazole, mercaptobenzotriazole, 5-methyl-1-benzotriazole, and combinations thereof. Other suitable corrosion inhibitors include film forming agents that are cyclic compounds, for example, imidazole, benzimidazole, triazole, and combinations thereof. Derivatives of benzotriazole, imidazole, benzimidazole, triazole, with hydroxy, amino, imino, carboxy, mercapto, nitro and alkyl substituted groups may also be used as corrosion inhibitors. Other corrosion inhibitors include urea and thiourea among others.

The residual composition included herein may include between about 0.2 vol % and about 2 vol % of sulfuric acid or derivative thereof, between about 0.2 vol % and about 2 vol % of phosphoric acid or derivative thereof, between about 0.1 wt. % and about 2 wt. % of a pH adjusting agent, between about 0.1 wt. % and about 2 wt. % of a chelating agent, between about 0.001 vol % and about 0.5 vol % of a passivating polymeric material, a pH between about 5 and about 10, and a solvent, such as water.

In any of the embodiments described herein, the preferred polishing compositions described herein are oxidizer-free compositions, for example, compositions free of oxidizers and oxidizing agents. Examples of oxidizers and oxidizing agents include, without limitation, hydrogen peroxide, ammonium persulfate, potassium iodate, potassium permnanganate, and cerium compounds including ceric nitrate, ceric ammonium nitrate, bromates, chlorates, chromates, iodic acid, among others.

Alternatively, the polishing compositions may include an oxidizing compound. Examples of suitable oxidizer compounds beyond those listed herein are nitrate compounds including ferric nitrate, nitric acid, and potassium nitrate. In one alternative embodiment of the compositions described herein, a nitric acid based electrolyte system, such as electrolytes and compounds having a nitrate group (NO₃¹⁻), such as nitric acid (HNO₃), and/or derivative salts thereof, including ferric nitrate (Fe(NO₃)₃), may be used in place of the sulfuric acid based electrolyte.

While the polishing compositions described above are free of oxidizers (oxidizer-free) and/or abrasive particles (abrasive-free), the polishing composition contemplates including one or more surface finish enhancing and/or removal rate enhancing materials including abrasive particles, one or more oxidizers, and combinations thereof. One or more surfactants may be used in the polishing composition to increase the dissolution or solubility of materials, such as metals and metal ions or by-products produced during processing, reduce any potential agglomeration of abrasive particles in the polishing composition, improve chemical stability, and reduce decomposition of components of the polishing composition. Suitable oxidizers and abrasives are described in co-pending U.S. patent application Ser. No. 10/378,097, filed on Feb. 26, 2004, which is incorporated by reference herein to the extent not inconsistent with the claimed aspects and disclosure herein.

Alternatively, the polishing composition may further include electrolyte additives including suppressors, enhancers, levelers, brighteners, stabilizers, and stripping agents to improve the effectiveness of the polishing composition in polishing of the substrate surface. For example, certain additives may decrease the ionization rate of the metal atoms, thereby inhibiting the dissolution process, whereas other additives may provide a finished, shiny substrate surface. The additives may be present in the polishing composition in concentrations up to about 15% by weight or volume, and may vary based upon the desired result after polishing.

Further examples of additives to the polishing composition are more fully described in U.S. patent application Ser. No. 10/141,459, filed on May 7, 2002, which is incorporated by reference herein to the extent not inconsistent with the claimed aspects and disclosure herein.

The balance or remainder of the residue polishing composition described above is a solvent, such as a polar solvent, including water, preferably deionized water. Other solvents may include, for example, organic solvents, such as alcohols or glycols, and in some embodiments may be combined with water. The amount of solvent may be used to control the concentrations of the various components in the composition. For example, the electrolyte may be concentrated up to three times as concentrated as described herein and then diluted with the solvent prior to use of diluted at the processing station as described herein.

Generally, Ecmp solutions are much more conductive than traditional CMP solutions. The Ecmp solutions have a conductivity of about 10 milliSiemens (mS) or higher, while traditional CMP solutions have a conductivity from about 3 mS to about 5 mS. The conductivity of the Ecmp solutions greatly influences the rate at which the Ecmp process advances, i.e., more conductive solutions have a faster material removal rate. For removing bulk material, the Ecmp solution has a conductivity of about 10 mS or higher, preferably in a range between about 40 mS and about 80 mS, for example, between about 50 mS and about 70 mS. For residual material, the Ecmp solution has a conductivity of about 10 mS or higher, preferably in a range between about 30 mS and about 60 mS, for example, between about 40 mS and about 55 mS.

It has been observed that a substrate processed with the polishing composition described herein has improved surface finish, including less surface defects, such as dishing, erosion (removal of dielectric material surrounding metal features), and scratches, as well as improved planarity. The compositions described herein may be further disclosed by the examples as follows.

### EXAMPLES OF POLISHING COMPOSITIONS AND PROCESSES

Examples of polishing compositions for polishing barrier material, such as titanium and/or titanium nitride are provided as follows.

### Example #1

about 8 wt. % of 85% aqueous phosphoric acid solution;

about 5 wt. % of ethylenediamine;

about 3 wt. % of glycine;

about 1 wt. % of 98% ammonium hydrogen citrate;

potassium hydroxide to provide a pH of about 3.5; and

water.

### Example #2

about 8 wt. % of 85% aqueous phosphoric acid solution;

about 5 wt. % of ethylenediamine;

about 3 wt. % of glycolic acid;

about 1 wt. % of 98% ammonium hydrogen citrate;

potassium hydroxide to provide a pH of about 3.5;

and water.

### Example #3

about 5 wt. % of 85% aqueous phosphoric acid solution;

about 3 wt. % of ethylenediamine;

about 3 wt. % of glycolic acid;

about 1 wt. % of 98% ammonium hydrogen citrate;

potassium hydroxide to provide a pH of about 3.5;

and water.

### Example #4

A tungsten plated substrate with 300 mm diameter was polished and planarized using the following polishing composition within a modified cell on a REFLEXION® system, available from Applied Materials, Inc., of Santa Clara, Calif. A substrate having a tungsten layer of about 4,000 Å thick on a barrier layer was placed onto a carrier head in an apparatus having a first Ecmp platen with a first polishing article disposed thereon. The tungsten material was removed by a two step process to expose the underlying barrier material of titanium nitride. The substrate was then transferred to a second (or third) Ecmp platen having a fully conductive polishing article disposed thereon. A barrier polishing composition was supplied to the platen at a rate of about 100 mL/min, and the first polishing composition comprising:
about 8 wt. % of 85% aqueous phosphoric acid solution;
about 5 wt. % of ethylenediamine;
about 3 wt. % of glycine;
about 1 wt. % of 98% ammonium hydrogen citrate;
potassium hydroxide to provide a pH of about 3.5; and
water.

The substrate was contacted with the conductive polishing article at a contact pressure of about 1 psi with a platen rotational rate of about 21 rpm, a carrier head rotational rate of about 30 rpm and a bias of about 3.2 volts was applied during the process. The substrate was polished and examined, and minimal dishing and erosion of the substrate surface was observed.

### Example #5

A tungsten plated substrate with 300 mm diameter was polished and planarized using the following polishing composition within a modified cell on a REFLEXION® system, available from Applied Materials, Inc., of Santa Clara, Calif. A substrate having a tungsten layer of about 4,000 Å thick on a barrier layer was placed onto a carrier head in an apparatus having a first Ecmp platen with a first polishing article disposed thereon. The tungsten material was removed by a two step process to expose the underlying barrier material of titanium nitride. The substrate was then transferred to a second (or third) Ecmp platen having a fully conductive polishing article disposed thereon. A barrier polishing composition was supplied to the platen at a rate of about 100 mL/min, and the first polishing composition comprising:

about 8 wt. % of 85% aqueous phosphoric acid solution;

about 5 wt. % of ethylenediamine;

about 3 wt. % of glycolic acid;

about 1 wt. % of 98% ammonium hydrogen citrate;

potassium hydroxide to provide a pH of about 3.5;

and water.

The substrate was contacted with the conductive polishing article at a contact pressure of about 1 psi with a platen rotational rate of about 21 rpm, a carrier head rotational rate of about 30 rpm and a bias of about 3.2 volts was applied during the process. The substrate was polished and examined, and minimal dishing and erosion of the substrate surface was observed.

### Example #6

A tungsten plated substrate with 300 mm diameter was polished and planarized using the following polishing composition within a modified cell on a REFLEXION® system, available from Applied Materials, Inc., of Santa Clara, Calif. A substrate having a tungsten layer of about 4,000 Å thick on a barrier layer was placed onto a carrier head in an apparatus having a first Ecmp platen with a first polishing article disposed thereon. The tungsten material was removed by a two step process to expose the underlying barrier material of titanium nitride. The substrate was then transferred to a second (or third) Ecmp platen having a fully conductive polishing article disposed thereon. A barrier polishing composition was supplied to the platen at a rate of about 100 mL/min, and the first polishing composition comprising:

about 5 wt. % of 85% aqueous phosphoric acid solution;

about 3 wt. % of ethylenediamine;

about 3 wt. % of glycolic acid;

about 1 wt. % of 98% ammonium hydrogen citrate;

potassium hydroxide to provide a pH of about 3.5;

and water.

The substrate was contacted with the conductive polishing article at a contact pressure of about 1 psi with a platen rotational rate of about 21 rpm, a carrier head rotational rate of about 30 rpm and a bias of about 3.2 volts was applied during the process. The substrate was polished and examined, and minimal dishing and erosion of the substrate surface was observed

While the foregoing is directed to embodiments of the present invention, other and further embodiments of the invention may be devised without departing from the basic scope thereof, and the scope thereof is determined by the claims that follow.

What is claimed is:

1. A composition for removing at least a barrier material from a substrate surface, comprising:
an acid based electrolyte system;
a first chelating agent having a nitrogen containing functional group;
a second chelating agent having a carboxylate functional group;
an organic acid salt;
a pH adjuster to maintain a pH between about 3 and about 11; and
a solvent.

2. The composition of claim 1, further comprising one or more activating agents, one or more etching inhibitors, one or more oxidizers, or combinations thereof.

3. The composition of claim 1, wherein the acid based electrolyte system comprises sulfuric acid based electrolytes, phosphoric acid based electrolyte, or combinations thereof.

4. The composition of claim 1, wherein the first chelating agent comprises a compound having one or more functional groups selected from the group consisting of amine groups, amide groups, pyridyl groups, and combinations thereof, and the second chelating agent comprises a compound having one or more functional groups selected from the group consisting of carboxylate groups, hydroxyl groups, and combinations thereof.

5. The composition of claim 4, wherein the composition has a pH of between about 3 and about 7 and the chelating agent comprises a compound having one or more functional groups selected from the group consisting of carboxylate groups.

6. The composition of claim 4, wherein the composition has a pH of between about 6 and about 8 and the chelating agent comprises a compound having one or more functional groups selected from the group consisting of amine groups, amide groups, carboxylate groups, dicarboxylate groups, tri-carboxylate groups, hydroxyl groups, pyridyl groups, and combinations thereof.

7. The composition of claim 6, wherein the composition has a pH of between about 6 and about 8 and the chelating agent is selected from the group consisting of comprises glycine, ethylene glycol, glycolic acid, and combinations thereof.

8. The composition of claim 4, wherein the composition has a pH of between about 7 and about 11 and the chelating agent comprises ethylenediamine, 2,2-dipyroiyl, or combinations thereof.

9. The composition of claim 1, wherein the one or more activating agents are selected from the group consisting of abrasive particles, metal ions, and combinations thereof.

10. The composition of claim 2, wherein the organic acid salt compound is selected from the group consisting of ammonium citrate, ammonium hydrogen citrate, potassium citrate, potassium hydrogen citrate, ammonium succinate, potassium succinate, ammonium oxalate, potassium oxalate, potassium tartrate, and combinations thereof.

11. The composition of claim 1, wherein the composition comprises:
about 8 wt. % of phosphoric acid;
about 5 wt. % of ethylenediamine;
about 3 wt. % of glycine;
about 1 wt. % of ammonium hydrogen citrate;
potassium hydroxide to provide a pH of about 3.5; and
water.

12. The composition of claim 1, wherein the composition comprises:
about 8 wt. % of phosphoric acid;
about 5 wt. % of ethylenediamine;
about 3 wt. % of glycolic acid;
about 1 wt. % of ammonium hydrogen citrate;
potassium hydroxide to provide a pH of about 3.5;
and water.

13. A method of processing a substrate comprising a dielectric surface, feature definitions formed in the dielectric surface, a barrier material disposed in the feature definitions and the dielectric surface, and a conductive material disposed on the barrier material, the method comprising:
polishing the conductive material to expose the barrier material;
disposing the substrate in a process apparatus comprising a first electrode and a second electrode, wherein the substrate is in electrical contact with the second electrode;
providing a polishing composition between the first electrode and the substrate, wherein the polishing composition comprises:
an acid based electrolyte system;
a first chelating agent having a nitrogen containing functional group;
a second chelating agent having a carboxylate functional group;
an organic acid salt;
a pH adjuster to maintain a pH between about 3 and about 11; and
a solvent;
applying a pressure between the substrate and a polishing article by use of a polishing head;
providing relative motion between the substrate and the polishing article by mechanical means;
applying a bias between the first electrode and the second electrode; and
removing barrier material from the dielectric surface.

14. The method of claim 13, wherein the bias is applied to the substrate to initiate an anodic dissolution at a current density between about 0.01 milliamps/cm² and about 100 milliamps/cm².

15. The method of claim 13, wherein the pressure applied between the substrate and polishing article is between about 0.1 and about 1.0 psi.

16. The method of claim 13, wherein providing relative motion between the substrate and the polishing article comprises rotating the substrate at a rotational rate between about 5 rpm and about 45 rpm, and rotating the polishing article at a rotational rate between about 3 rpm and about 45 rpm.

17. The method of claim 13, wherein the composition further comprises one or more activating agents, one or more etching inhibitors, one or more oxidizers, or combinations thereof.

18. The method of claim 13, wherein the acid based electrolyte system comprises sulfuric acid based electrolytes, phosphoric acid based electrolyte, or combinations thereof.

19. The method of claim 13, wherein the first chelating agent comprises a compound having one or more functional groups selected from the group consisting of amine groups, amide groups, pyridyl groups, and combinations thereof, and the second chelating agent comprises a compound having one or more functional groups selected from the group consisting of carboxylate groups, hydroxyl groups, and combinations thereof.

20. The method of claim 13, wherein the composition has a pH of between about 3 and about 7 and the chelating agent comprises a compound having one or more functional groups selected from the group consisting of carboxylate groups.

21. The method of claim 13, wherein the composition has a pH of between about 6 and about 8 and the chelating agent comprises a compound having one or more functional groups selected from the group consisting of amine groups, amide groups, carboxylate groups, dicarboxylate groups, tri-carboxylate groups, hydroxyl groups, pyridyl groups, and combinations thereof.

22. The method of claim 21, wherein the composition has a pH of between about 6 and about 8 and the chelating agent is selected from the group consisting of comprises glycine, ethylene glycol, glycolic acid, and combinations thereof.

23. The method of claim 13, wherein the composition has a pH of between about 7 and about 11 and the chelating agent comprises ethylenediamine, 2,2-dipyroiyl, or combinations thereof.

24. The method of claim 17, wherein the one or more activating agents are selected from the group consisting of abrasive particles, metal ions, and combinations thereof.

25. The method of claim 17, wherein the organic acid salt compound is selected from the group consisting of ammonium citrate, ammonium hydrogen citrate, potassium citrate, potassium hydrogen citrate, ammonium succinate, potassium succinate, ammonium oxalate, potassium oxalate, potassium tartrate, and combinations thereof.

26. The method of claim 12, wherein the composition comprises:
about 8 wt. % of phosphoric acid;
about 5 wt. % of ethylenediamine;
about 3 wt. % of glycine;
about 1 wt. % of ammonium hydrogen citrate;
potassium hydroxide to provide a pH of about 3.5; and
water.

27. The method of claim 12, wherein the composition comprises:
about 8 wt. % of phosphoric acid;
about 5 wt. % of ethylenediamine;
about 3 wt. % of glycolic acid;
about 1 wt. % of ammonium hydrogen citrate;
potassium hydroxide to provide a pH of about 3.5;
and water.
